(19) United States
(12) Patent Application Publication
(10) Pub. No.: US 2026/0354226 A1
(43) Pub. Date: Nov. 5, 2026

(54) SEMICONDUCTOR PACKAGE AND METHOD FOR FORMING THE SAME

(71) Applicant: Taiwan Semiconductor Manufacturing Co., Ltd., Hsinchu (TW)

(72) Inventors: Yao-Cheng Wu, Changhua County (TW); Jeng-An Wang, Hsinchu (TW); Hao-Cheng Hou, Hsinchu (TW); Wei-Yu Chen, Hsinchu (TW); Tsung-Ding Wang, Tainan (TW); Hao-Yi Tsai, Hsinchu (TW)

(21) Appl. No.: 19/731,560

(22) Filed: Jul. 6, 2026

Related U.S. Application Data
(63) Continuation of application No. 18/738,774, filed on Jun. 10, 2024.

(51) Int. Cl. H10W 70/63; H10W 70/65; H10W 70/09; H10W 70/60; H10W 70/652; H10W 72/00; H10W 90/00; H10W 90/10

(52) U.S. Cl. CPC H10W 70/635; H10W 70/65; H10W 70/09; H10W 70/60; H10W 70/6528; H10W 72/0198; H10W 90/00; H10W 90/10

(57) ABSTRACT

A semiconductor package includes an interconnect structure, wherein interconnect structure include a semiconductor substrate comprising a first side and a second side opposite to the first side, a routing structure disposed at the first side of the semiconductor substrate, wherein a first die is electrically coupled to a second die through at least the routing structure, and a metallization pattern disposed at the second side of the semiconductor substrate, wherein the metallization pattern comprises a first metallization feature and a second metallization feature. The second metallization feature is electrically isolated, and a through via extending through the semiconductor substrate electrically couples the routing structure to the first metallization feature. The structure may be formed using a process that involves only bonding / debonding of two carrier substrates.

### PRIORITY CLAIM AND CROSS-REFERENCE

This application is a continuation of U.S. Patent Application No. 18/738,774, filed on Jun. 10, 2024, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5A, 6, and 7 are cross-sectional views of intermediate stages in the manufacturing of interconnect structures, in accordance with some embodiments.

FIG. 5B is a top view of a metallization feature, in accordance with some embodiments.

FIGS. 8-17 are cross-sectional views of intermediate stages in the manufacturing of a semiconductor package, in accordance with some embodiments.

FIGS. 18-19 are cross-sectional views of intermediate stages in the manufacturing of a semiconductor package, in accordance with some embodiments.

FIG. 20 is a cross-sectional view of interconnect structures in accordance with some embodiments, and FIG. 21 is a cross-sectional view of a semiconductor package containing the interconnect structure.

FIG. 22 is a cross-sectional view of interconnect structures in accordance with some embodiments, and FIG. 23 is a cross-sectional view of a semiconductor package containing the interconnect structure.

FIGS. 24-26 are cross-sectional views of intermediate stages in the manufacturing of interconnect structures in accordance with some embodiments, and FIG. 27 is a cross-sectional view of a semiconductor package containing the interconnect structure.

FIGS. 28A, 28B, and 29-30 are cross-sectional views of intermediate stages in the manufacturing of interconnect structures in accordance with some embodiments, and FIG. 31 is a cross-sectional view of a semiconductor package containing the interconnect structure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor package containing an interconnect structure is provided and manufactured by a simplified method. For example, in some embodiments, fewer carrier substrates may be used for forming a semiconductor package, including the interconnect structure, redistribution structures at opposite sides of the interconnect structure, and through vias connecting the redistribution structures. In an embodiment, the interconnect structure includes electrically isolated metallization features as alignment marks, which may help equipment align the interconnect structure and/or the semiconductor package to a suitable direction in the manufacturing of the semiconductor package, such as when forming a back-side redistribution structure.

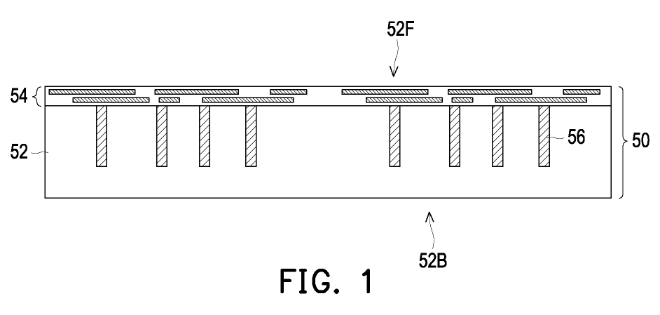

FIGS. 1-4, 5A, 6, and 7 illustrate cross-sectional views of intermediate stages in the manufacturing of interconnect structures, in accordance with some embodiments. Referring to FIG. 1, an interconnect structure 50 including a semiconductor substrate 52, a routing structure 54, and through vias 56 are provided. The interconnect structure 50 as illustrated in FIG. 1 can be obtained or formed. The semiconductor substrate 52 has a front side 52F and a back side 52B opposite to the front side 52F. In some embodiments, the interconnect structure 50 may be an interposer and does not include active devices therein, although the interposer may include passive devices. In some embodiments, the interconnect structure 50 includes active devices (e.g., transistors or memory devices) formed in and/or on the front surface of the semiconductor substrate 52 (e.g., a surface at the front side 52F of semiconductor substrate 52). The semiconductor substrate 52 may be a bulk semiconductor substrate, a semiconductor-on-insulator (SOI) substrate, a multi-layered semiconductor substrate, or the like. The semiconductor substrate 52 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used.

The routing structure 54 is over the front side 52F of the semiconductor substrate 52, and is used to electrically connect the devices (if any) of the semiconductor substrate 52 and/or the devices attached to the interconnect structure 50. The routing structure 54 may include one or more dielectric layer(s) and respective metallization layer(s) in the dielectric layer(s). Acceptable dielectric materials for the dielectric layers include an oxide, a nitride, a carbide, a combination thereof, or the like. For example, the dielectric material may include silicon oxide, aluminum oxide, silicon nitride; silicon oxynitride, silicon carbide, silicon oxycarbide, silicon carbonitride, silicon oxycarbonitride, a combination thereof, or the like. Other dielectric materials may also be used, such as a polymer such as polybenzoxazole (PBO), polyimide, a benzocyclobutene (BCB) based polymer, or the like. The metallization layer(s) may include conductive vias and/or conductive lines to interconnect any devices together and/or to an external device. The metallization layer(s) may be formed of a conductive material, such as a metal, which may be copper, cobalt, aluminum, gold, combinations thereof, or the like. The routing structure 54 may be formed by a damascene process, such as a single damascene process, a dual damascene process, a combination therefore, or the like.

The through vias 56 extend into the routing structure 54 and/or the semiconductor substrate 52. The through vias 56 are electrically connected to metallization layer(s) of the routing structure 54. As an example to form the through vias 56, recesses can be formed in the routing structure 54 and/or the semiconductor substrate 52 by, for example, etching, milling, laser techniques, a combination thereof, and/or the like. A thin dielectric material may be formed in the recesses, such as by using an oxidation technique. A thin barrier layer may be conformally deposited in the openings, such as by chemical vapor deposition (CVD), atomic layer deposition (ALD), physical vapor deposition (PVD), thermal oxidation, a combination thereof, and/or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer are removed from a surface of the routing structure 54 or the semiconductor substrate 52 by, for example, a CMP. Remaining portions of the barrier layer and conductive material form the through vias 56.

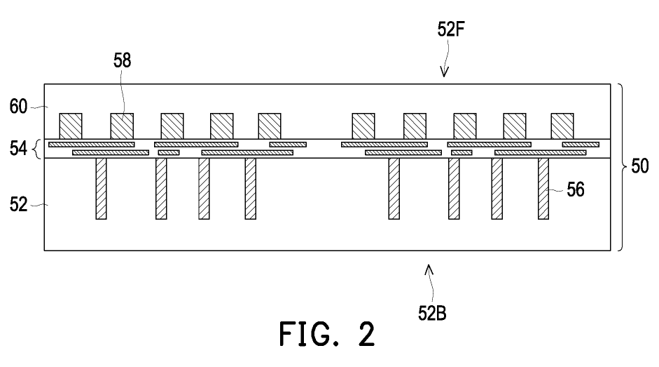

In FIG. 2, conductive features 58 are formed at the front side 52F of the semiconductor substrate 52, such as formed over the routing structure 54. The conductive features 58 may be conductive pillars, conductive pads, or the like. The conductive features 58 can be formed of a metal, such as copper, aluminum, an alloy thereof, or the like, and can be formed by, for example, plating, or the like. In some embodiments, the conductive features 58 are copper pillars.

An encapsulant 60 is disposed at the front side 52F of the semiconductor substrate 52. The encapsulant 60 may bury the conductive features 58, such that the top surface of the encapsulant 60 is above the top surfaces of the conductive features 58. The encapsulant 60 laterally encapsulates the conductive features 58. The encapsulant 60 may be a polymer material, such as a polyimide, PBO, BCB, a combination thereof, or the like, and which may be formed by CVD, coating, or any suitable techniques. Alternatively, the encapsulant 60 may be a molding compound, which may include epoxy-based resins with or without particle fillers, and may be formed by compression molding, transfer molding, or the like.

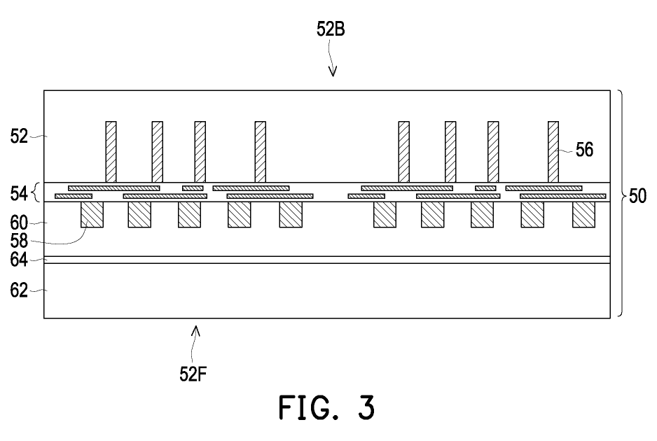

In FIG. 3, the interconnect structure 50 is flipped over and placed on a carrier substrate 62 or other suitable support structure for subsequent processing. For example, the encapsulant 60 may be attached to carrier substrate 62 by a release layer 64. In some embodiments, the carrier substrate 62 is a substrate such as a bulk semiconductor having a wafer or panel shape or the like. For example, the carrier substrate 62 is a blank silicon wafer. The release layer 64 may be formed of a polymer-based material, which may be removed along with the carrier substrate 62 from the structure after processing. In some embodiments, the bonding related material of release layer 64 can lose its adhesive property when heated, such as by heating or a light-to-heat-conversion (LTHC). In other embodiments, the bonding related material is removed, such as by mechanical grinding or the like.

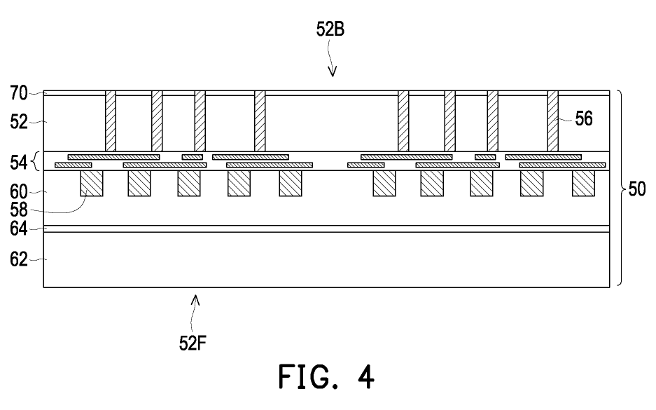

In FIG. 4, the interconnect structure 50 is thinned to expose the through vias 56. Exposure of the through vias 56 may be accomplished by a thinning process, such as a grinding process, a chemical-mechanical polish (CMP), an etch-back, combinations thereof, or the like. In the illustrated embodiment, a recessing process is performed to recess the back surface of the semiconductor substrate 52 such that the through vias 56 protrude from the semiconductor substrate 52 at the back side 52B of the semiconductor substrate 52. The recessing process may be, e.g., a suitable etch-back process, chemical-mechanical polish (CMP), or the like. In some embodiments, the thinning process for exposing the through vias 56 includes a CMP, and the through vias 56 protrude from the semiconductor substrate 52 as a result of dishing that occurs during the CMP or a separate recess etch process. An insulating layer 70 is formed at the back side 52B of the semiconductor substrate 52, laterally surrounding the protruding portions of the through vias 56. In some embodiments, the insulating layer 70 is formed of a silicon-containing insulator, such as silicon nitride, silicon oxide, silicon oxynitride, or the like, and may be formed by a suitable deposition method such as spin coating, CVD, plasma-enhanced CVD (PECVD), high-density plasma CVD (HDP-CVD), or the like. Initially, the insulating layer 70 may bury the through vias 56. A removal process can be applied to the various layers to remove excess materials over the through vias 56. The removal process may be a planarization process such as a chemical mechanical polish (CMP), an etch-back, combinations thereof, or the like. After planarization, the exposed surfaces of the through vias 56 and the insulating layer 70 are coplanar (within process variations).

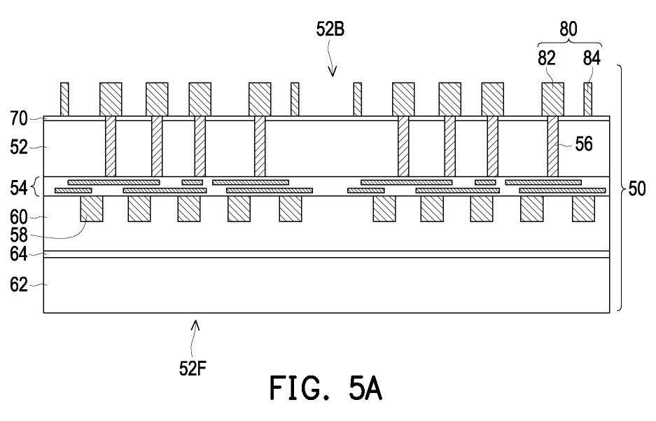

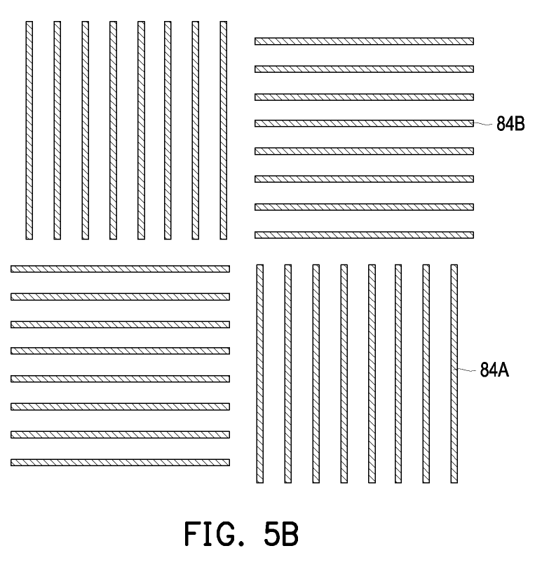

In FIG. 5A, after exposing the through vias 56 and forming the insulating layer 70, metallization features 80 are formed at the back side 52B of the semiconductor substrate 52. The metallization features 80 may be conductive pillars, pads, or the like. In some embodiments, the metallization features 80 includes first metallization features 82 and second metallization features 84. External connections can be electrically connected to the through vias 56 and other conductive features of the interconnect structure 50 from the back side 52B of the semiconductor substrate 52 through the first metallization features 82. In some embodiments, the first metallization features 82 are disposed over and connected to the through vias 56. The first metallization features 82 may have a bottom width greater than a width of the through vias 56 so that the first metallization features 82 may extend along a major surface of insulating layer 70 facing away from the semiconductor substrate 52. The second metallization features 84 are formed over the insulating layer 70, in accordance with some embodiments. The second metallization features 84 are electrically isolated. In some embodiments, the second metallization features 84 may be alignment marks that may help the interconnect structure 50 be aligned to a suitable location in the subsequent manufacturing processes.

Although FIG. 5A illustrates one second metallization feature 84 on either side of each grouping of the first metallization features 82, each of the second metallization features 84 illustrated in FIG. 5A may include multiple discrete features arranged in a matrix. For example, FIG. 5B shows an enlarged top view of a matrix of the second metallization features 84. In FIG. 5B, the second metallization feature 84 is a matrix of strips. For example, the second metallization features 84 may include a plurality of first strips 84A extending in a first direction and a plurality of second strips 84B extending in a second direction substantially perpendicular to the first direction, in accordance with some embodiments. In some embodiments, the matrix of strips may also be replaced with any suitable shapes that can help align the direction of interconnect structure 50.

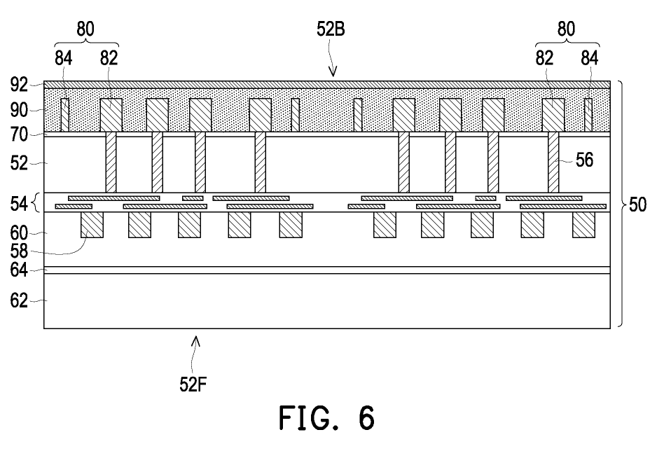

In FIG. 6, an encapsulant 90 is disposed over the metallization features 80 at the back side 52B of the semiconductor substrate 52. The encapsulant 90 may bury the metallization features 80, such that the top surface of the encapsulant 90 is above the top surfaces of the metallization features 80. The encapsulant 90 laterally encapsulates the first metallization features 82 and the second metallization features 84. The encapsulant 90 may be a polymer material, such as polyimide, PBO, BCB, a combination thereof, or the like, and which may be formed by CVD, coating, or any suitable techniques. Alternatively, the encapsulant 90 includes a molding compound, which may include epoxy-based resins with or without particle fillers, and may be formed by compression molding, transfer molding, or the like. After the encapsulant 90 is formed, an adhesive film 92 is applied onto the encapsulant 90. The adhesive film 92 may be any suitable insulating adhesive, including a die-attach film (DAF) or the like.

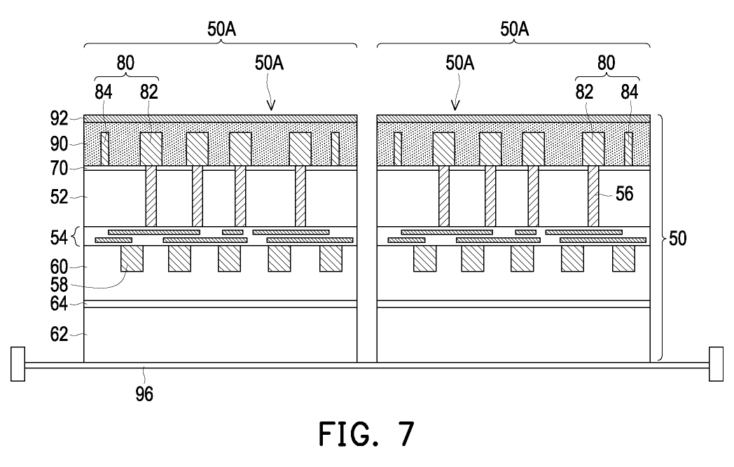

The processes discussed above may be performed at the wafer level or panel level, wherein the interconnect structure 50 is wafer-sized or panel-sized, and a singulation process may be performed. For example, referring to FIG. 7, the interconnect structure 50 may be placed on a tape 96, and a singulation process is performed along scribe regions to scribe the interconnect structure 50 to singulated interconnect structures 50A. The singulation process may include sawing the interconnect structure 50 by rotating blades and/or ablating the interconnect structure 50 by laser beams in a single step. For example, the singulation process may include scribing the adhesive film 92, the encapsulant 90, the insulating layer 70, the semiconductor substrate 52, the routing structure 54, the encapsulant 60, the release layer 64, and the carrier substrate 62. In some embodiments, as a result of the singulation process, the outer sidewalls of the adhesive film 92, the encapsulant 90, the insulating layer 70, the semiconductor substrate 52, the routing structure 54, the encapsulant 60, the release layer 64, and the carrier substrate 62 are laterally coterminous.

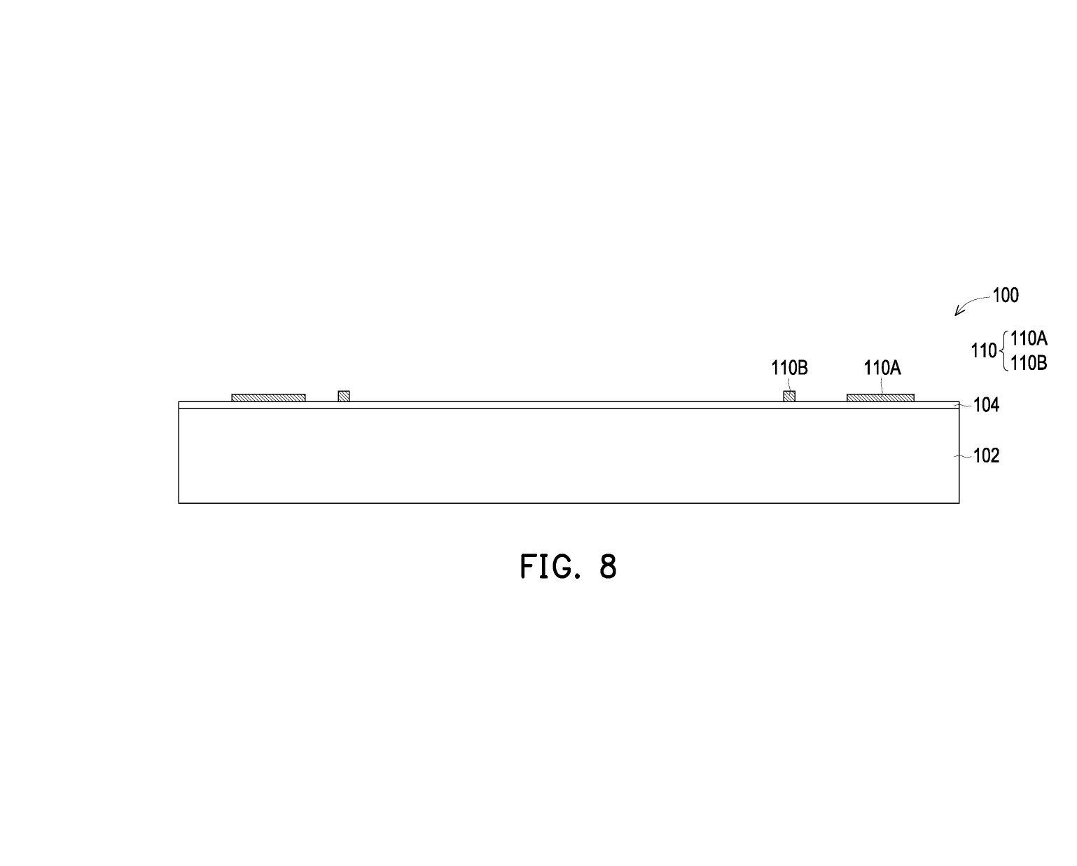

FIG. 8-19 illustrate cross-sectional views of intermediate stages in the manufacturing of a semiconductor package 100, in accordance with some embodiments. In FIG. 8, a first carrier substrate 102 is provided, and a release layer 104 is formed on the first carrier substrate 102. The first carrier substrate 102 may be a glass carrier substrate, a ceramic carrier substrate, or the like. The first carrier substrate 102 may be a wafer or a panel, such that multiple packages can be formed on the first carrier substrate 102 simultaneously.

The release layer 104 may be formed of a polymer-based material, which may be removed along with the first carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the first carrier substrate 102, or may be the like.

A metallization pattern 110 may be formed on the release layer 104. The metallization pattern 110 may include one or more first metallization features 110A and one or more second metallization features 110B, in accordance with some embodiments. As an example to form the metallization pattern 110, a seed layer is formed over the release layer 104. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by spin coating or the like and may be exposed to light for patterning. The pattern of the photoresist corresponds to the metallization pattern 110. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 110.

In some embodiments, the first metallization features 110A are pads allowing to form through vias 116 thereon in subsequent processes. The first metallization features 110A may have a circular shape, an oval shape, a rectangular shape, a square shape, the like, or combinations thereof in a top view. In some embodiments, the second metallization features 110B provide the function of alignment marks, such as helping equipment to identify where to place the interconnect structure 50A on the carrier substrate 62 and/or or align the carrier substrate 62 to a suitable direction. The second metallization features 110B may have a similar shape as the second metallization features 84 in a top view.

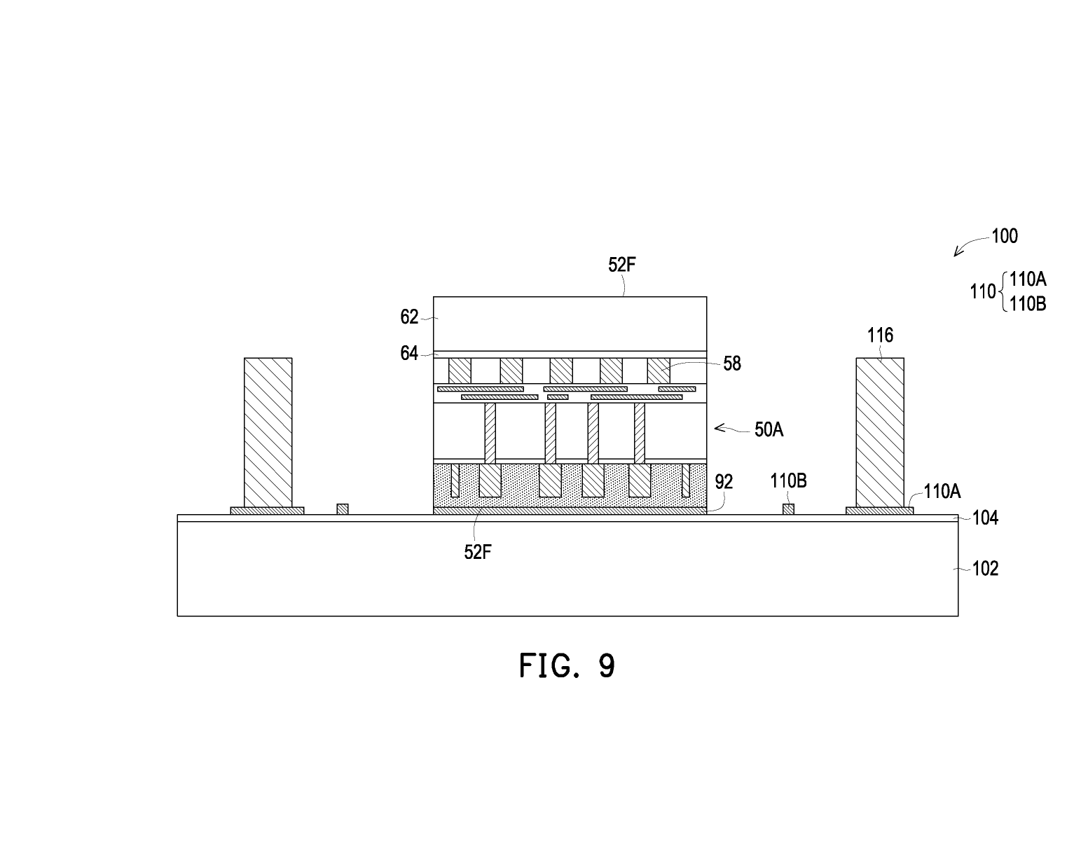

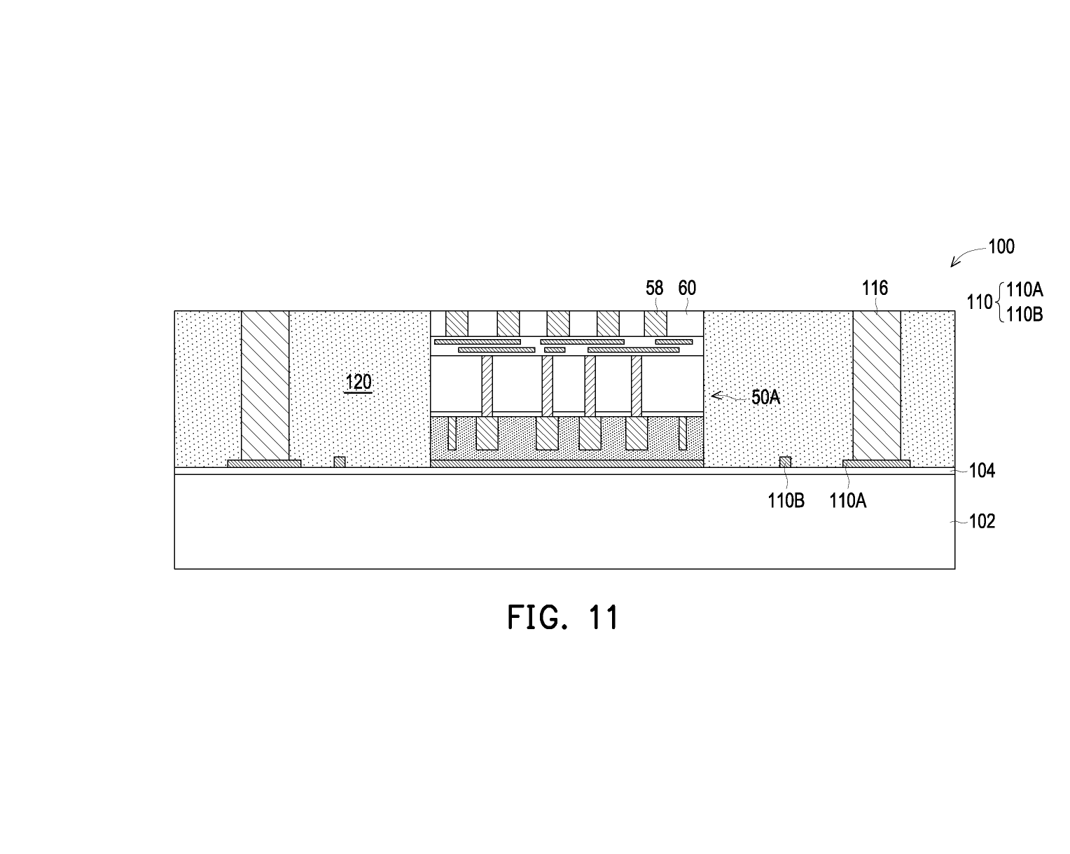

In FIG. 9, through vias 116 are formed over the first metallization features 110A of the metallization pattern 110, in accordance with some embodiments. A photoresist is deposited over the first carrier substrate 102 and patterned to expose at least a portion of the first metallization features 110A while burying the second metallization features 110B. The photoresist may be formed by spin coating or the like and may be exposed to light for patterning. The pattern of the photoresist corresponds to the through vias 116. A conductive material is formed in the openings of the photoresist and on the exposed portions of the first metallization features 110A. The conductive material may comprise a metal, like copper, titanium, tungsten, aluminum, or the like. In some embodiments, the conductive material may be formed by plating, such as electroplating or electroless plating, or the like, directly on the first metallization features 110A without a seed layer. The photoresist may be removed after the through vias 116 are formed, by an acceptable ashing or stripping process, such as using an oxygen plasma or the like. In some embodiments, the through vias 116 have upper surfaces higher than an upper surface of the conductive features 58 and/or the release layer 64 in the intermediate structure illustrated in FIG. 9 to provide sufficient portions of through vias 116 able to be sacrificed in the subsequent planarization process (see FIG. 11).

The interconnect structure 50A is adhered to the release layer 104 by the adhesive film 92 with the front side 52F face up or facing away from the first carrier substrate 102. Although only one interconnect structure 50A is illustrated in FIG. 9, two or more interconnect structures 50A may be disposed over the carrier substrate 62, and the number of the interconnect structures 50A is not limited. In some embodiments, the interconnect structure 50A is disposed over carrier substrate 62 after the through vias 116 are formed, however, the interconnect structure 50A can also be disposed over the carrier substrate 62 before the formation of the through vias 116.

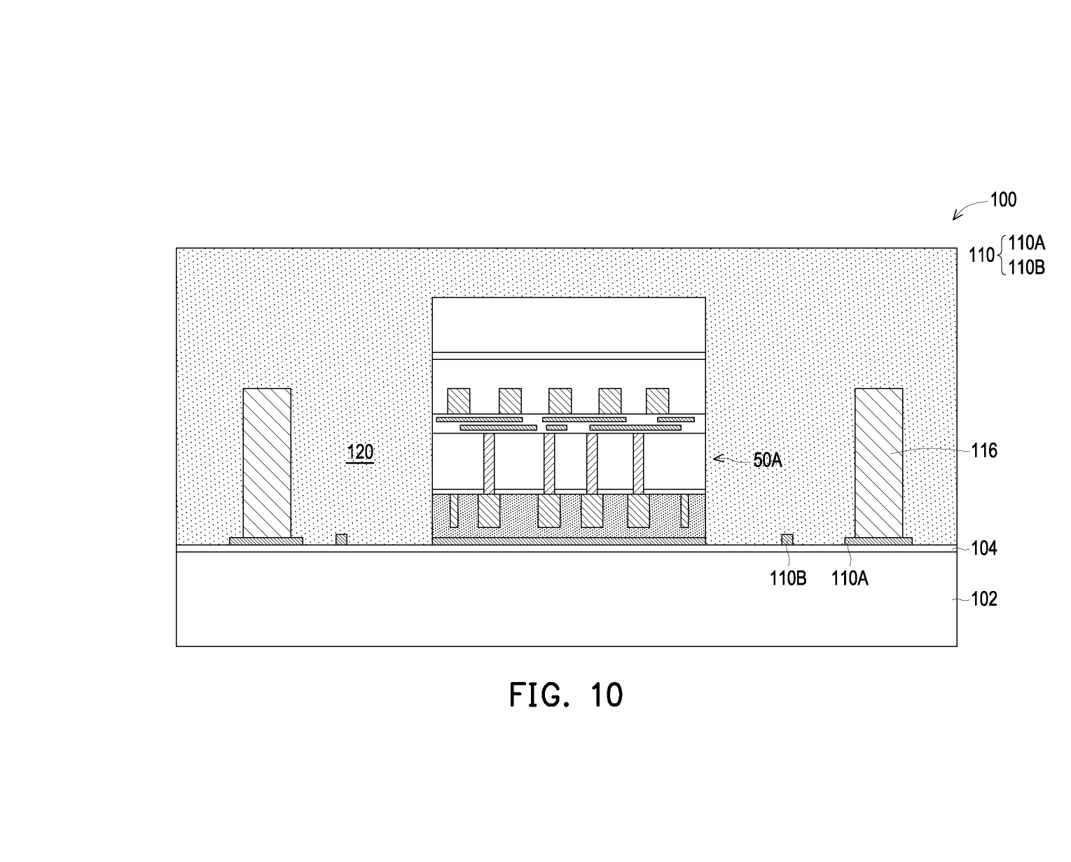

In FIG. 10, an encapsulant 120 is formed on and around the various components. After formation, the encapsulant 120 encapsulates the through vias 116 and interconnect structure 50A. The encapsulant 120 may be formed over the carrier substrate 62 such that the through vias 116 and/or the interconnect structure 50A are buried or covered. In some embodiments, the encapsulant 120 is also formed in gap regions between interconnect structures 50A when two or more interconnect structures 50A are disposed over the carrier substrate 62. The encapsulant 120 may be a molding compound, which may include a base material of a resin, an epoxy, or the like, and also include filler particles in the base material. The filler particles may be dielectric particles of SiO₂, Al₂O₃, or the like, and may have spherical shapes. Also, the spherical filler particles may have a plurality of different diameters. The encapsulant 120 may be applied by compression molding, transfer molding, or the like. For example, the encapsulant 120 may be applied in liquid or semi-liquid form and then subsequently cured.

In FIG. 11, a planarization process is performed on the encapsulant 120 and the encapsulant 60 to expose the through vias 116 and the conductive features 58. In some embodiments, a de-bonding process may be performed to detach the carrier substrate 62 from the encapsulant 60 before the planarization process. In some embodiments, the de-bonding process includes projecting a light such as a laser light or a UV light on the release layer 64 so that the release layer 64 decomposes and the first carrier substrate 102 can be removed. In some embodiments, the de-bonding process is skipped, and the planarization process includes removing the carrier substrate 62 and the release layer 64. Whether the de-bonding process is performed, the planarization process may also remove material of the through vias 116, encapsulant 60, and/or conductive features 58 until the conductive features 58 and through vias 116 are sufficiently exposed. Top surfaces of the through vias 116, conductive features 58, encapsulant 60, and encapsulant 120 are substantially coplanar after the planarization process within process variations. The planarization process may be, for example, a chemical-mechanical polish (CMP), a grinding process, or the like.

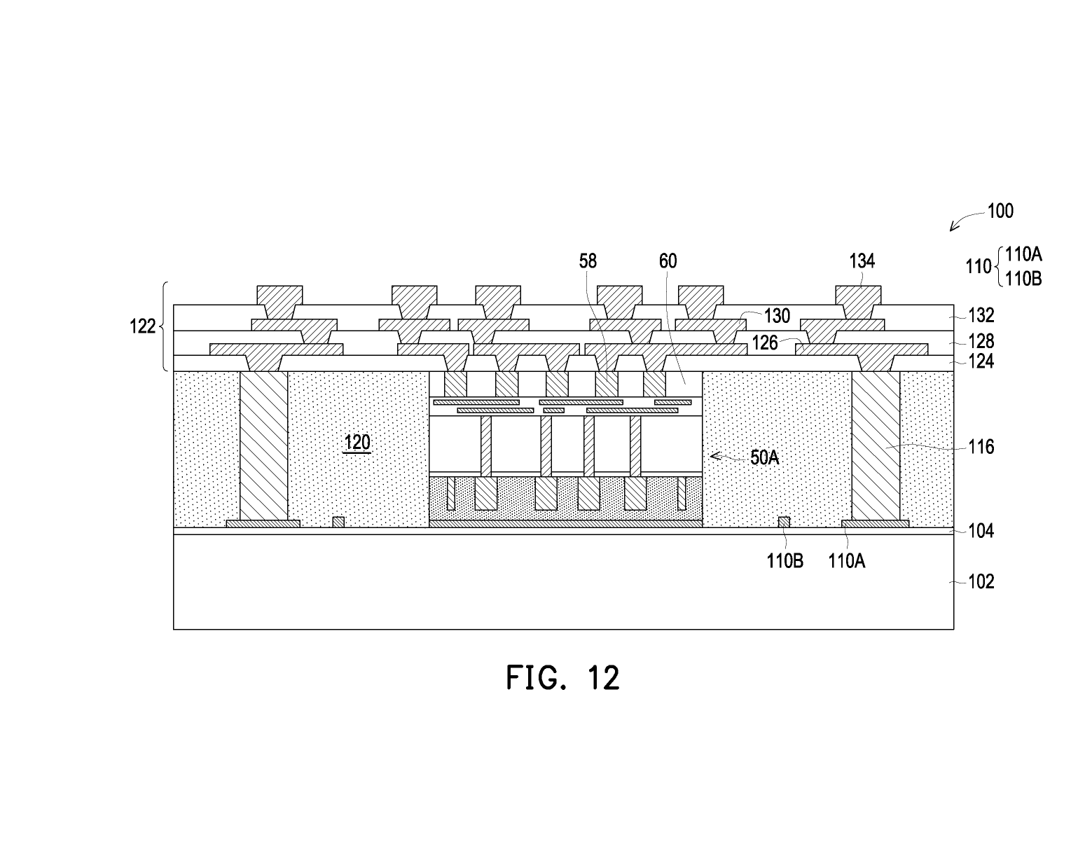

In FIG. 12, a front-side redistribution structure 122 is formed over the surfaces of the encapsulant 120, the through vias 116, and the interconnect structure 50A, in accordance with some embodiments. The front-side redistribution structure 122 may include dielectric layers 124, 128, and 132; and metallization patterns 126, 130, and 134. The metallization patterns may also be referred to as redistribution layers or redistribution lines. The front-side redistribution structure 122 is shown as an example of three dielectric layers and three layers of metallization patterns. More or fewer dielectric layers and metallization patterns may be formed in the front-side redistribution structure 122. If fewer dielectric layers and metallization patterns are to be formed, steps and processes discussed below may be omitted. If more dielectric layers and metallization patterns are to be formed, steps and processes discussed below may be repeated.

The formation of front-side redistribution structure 122 may include depositing the dielectric layer 124 on the top surfaces of the through vias 116, the encapsulant 120, the conductive features 58, and the encapsulant 60. In some embodiments, the dielectric layer 124 is formed of a photosensitive material such as PBO, polyimide, benzocyclobutene (BCB), or the like, which may be patterned using a lithography mask. The dielectric layer 124 may be formed by spin coating, lamination, CVD, the like, or a combination thereof. The dielectric layer 124 is then patterned. The patterning forms openings exposing the conductive features 58 and the through vias 116. The patterning may be performed by an acceptable process, such as by exposing and developing the dielectric layer 124 to light or by etching using, for example, an anisotropic etch.

The metallization pattern 126 is then formed. The metallization pattern 126 includes conductive elements extending along the major surface of the dielectric layer 124 and extending through the dielectric layer 124 to physically and electrically coupled to the conductive features 58 and the through vias 116. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, alloy thereof, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The combination of the conductive material and remaining portions of the seed layer form the metallization pattern 126.

Next, the dielectric layer 128 is deposited on the metallization pattern 126 and dielectric layer 124. The dielectric layer 128 may have a material similar to the dielectric layer 124, and may be formed in a similar manner. The metallization pattern 130 is then formed. The metallization pattern 130 includes portions on and extending along the major surface of the dielectric layer 138. The metallization pattern 130 further includes portions extending through the dielectric layer 128 to physically and electrically couple the metallization pattern 126. The metallization pattern 130 may be formed in a similar manner and of a similar material as the metallization pattern 126.

Next, the dielectric layer 132 is deposited on the metallization pattern 130 and dielectric layer 128. The dielectric layer 132 may have a material similar to the dielectric layer 124, and may be formed in a manner similar. The metallization pattern 134 is then formed. The metallization pattern 134 may be formed in a similar manner to the metallization pattern 134 and may include a similar material as the metallization pattern 126. The dielectric layer 132 is the topmost dielectric layer of the redistribution structure 112, and the metallization pattern 134 is the topmost metallization pattern for external connections, in accordance with some embodiments. The metallization pattern 134 may have via portions extending through the dielectric layer 132 to physically and electrically couple the metallization pattern 130. The metallization pattern 134 may be electrically coupled to the interconnect structure 50A and/or the through vias 116.

In some embodiments, the metallization pattern 134 also has bump portions on and extending along the major surface of the dielectric layer 132, and bump portions are formed for external connection to the front-side redistribution structure 122. As a result, external devices can be electrically coupled to the interconnect structure 50A and the through vias 116 through the front-side redistribution structure 122. In some embodiments, the interconnect structure 50A and the through vias 116 are electrically coupled through the front-side redistribution structure 122.

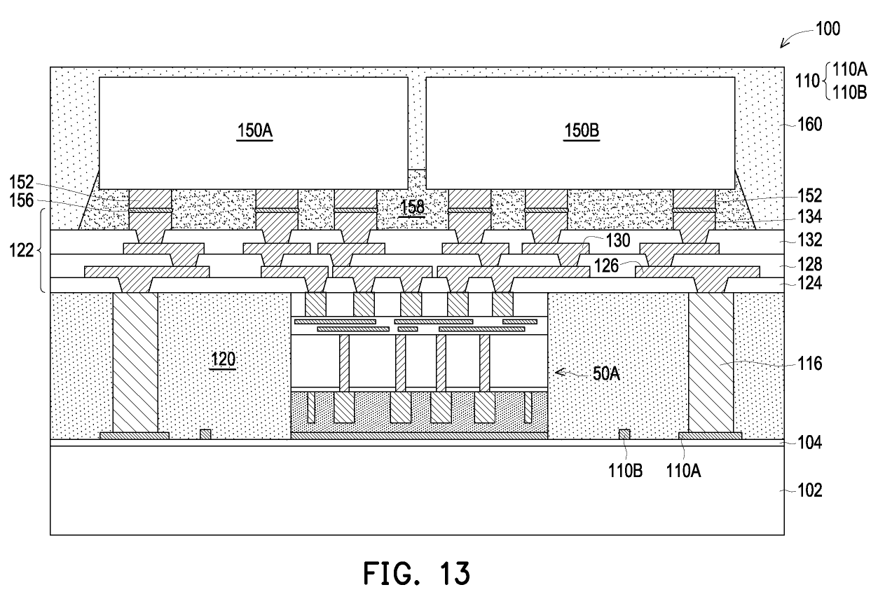

FIG. 13 illustrates one or more integrated circuit devices 150 attached to the interconnect structure 50 in accordance with some embodiments. In the example illustrated in FIG. 13, an integrated circuit device such as the first integrated circuit device 150A illustrated and a second integrated circuit devices 150B are attached to the front-side redistribution structure 122, wherein the first integrated circuit device 150A and the second integrated circuit devices 150B are collectively referred to as integrated circuit devices 150. The number of the first integrated circuit device 150A and the second integrated circuit device 150B are not limited and can be any number. Each of the first integrated circuit devices 150A and the second integrated circuit devices 150B may be an integrated circuit die, a stack of integrated circuit dies, a memory die, or a stack of memory dies. The first integrated circuit device 150A may have a different function than a function of the second integrated circuit device 150B, although they can have same or similar function. For example, the first integrated circuit device 150A may be a logic device, such as a central processing unit (CPU), graphics processing unit (GPU), system-on-a-chip (SoC), microcontroller, application-specific integrated circuit (ASIC), or the like. The second integrated circuit device 150B may be a memory device, such as a dynamic random-access memory (DRAM) device, static random access memory (SRAM) device, hybrid memory cube (HMC) module, a high bandwidth memory (HBM) module, or the like. The first integrated circuit device 150A and the second integrated circuit devices 150B may be formed in processes of a same technology node, or may be formed in processes of different technology nodes. For example, the first integrated circuit device 150A may be of a more advanced process node than the second integrated circuit device 150B, or vice versa.

The integrated circuit devices 150 may each comprise external connectors 152 for their external connections. The external connectors 152 of the integrated circuit devices 150 may be conductive pads or protruding bumps. For example, the external connectors 152 of the integrated circuit devices 150 may be bonded to the metallization patterns 134 through conductive connectors 156. The integrated circuit devices 150 may be placed on the front-side redistribution structure 122 using, e.g., a pick-and-place tool. The conductive connectors 156 may be formed of a reflowable conductive material, such as solder, and may further include other conductive materials such as copper, aluminum, gold, nickel, silver, palladium, tin, lead, the like, or a combination thereof. In some embodiments, the conductive connectors 156 are formed by initially forming a layer of solder through methods such as evaporation, electroplating, printing, solder transfer, ball placement, or the like. Attaching the integrated circuit devices 150 to the front-side redistribution structure 122 may include placing the integrated circuit devices 150 on the front-side redistribution structure 122 and reflowing the conductive connectors 156. The conductive connectors 156 form joints between corresponding metallization patterns 134 of the front-side redistribution structure 122 and the corresponding external connectors 152 of the integrated circuit devices 150, electrically connecting the integrated circuit devices 150 to the interconnect structure 50A and/or the through vias 116.

An underfill 158 may be formed around the conductive connectors 156, the metallization patterns 134, and the external connectors 152. The underfill 158 is disposed between integrated circuit devices 150 and the front-side redistribution structure 122. In some embodiments, the underfill 158 may be in physical contact with sidewalls of the integrated circuit devices 150. The underfill 158 may be formed of an underfill material such as an epoxy, or the like. The underfill 158 may be formed by a capillary flow process after the integrated circuit devices 150 are attached to the front-side redistribution structure 122, or may be formed by a suitable deposition method before the integrated circuit devices 150 are attached to the front-side redistribution structure 122. The underfill 158 may be applied in liquid or semi-liquid form and then subsequently cured.

An encapsulant 160 is formed over the front-side redistribution structure 122 and the various components on the front-side redistribution structure 122. After formation, the encapsulant 160 encapsulates the integrated circuit devices 150 and the underfill 158. As such, the integrated circuit devices 150 are buried or covered by the encapsulant 160. The encapsulant 160 may be a molding compound, which may include a base material of a resin, an epoxy, or the like, and also include filler particles in the base material. The filler particles may be dielectric particles of SiO2, Al2O3, or the like, and may have spherical shapes. Also, the spherical filler particles may have a plurality of different diameters. The encapsulant 160 may be applied by compression molding, transfer molding, or the like. For example, the encapsulant 160 may be applied in liquid or semi-liquid form and then subsequently cured.

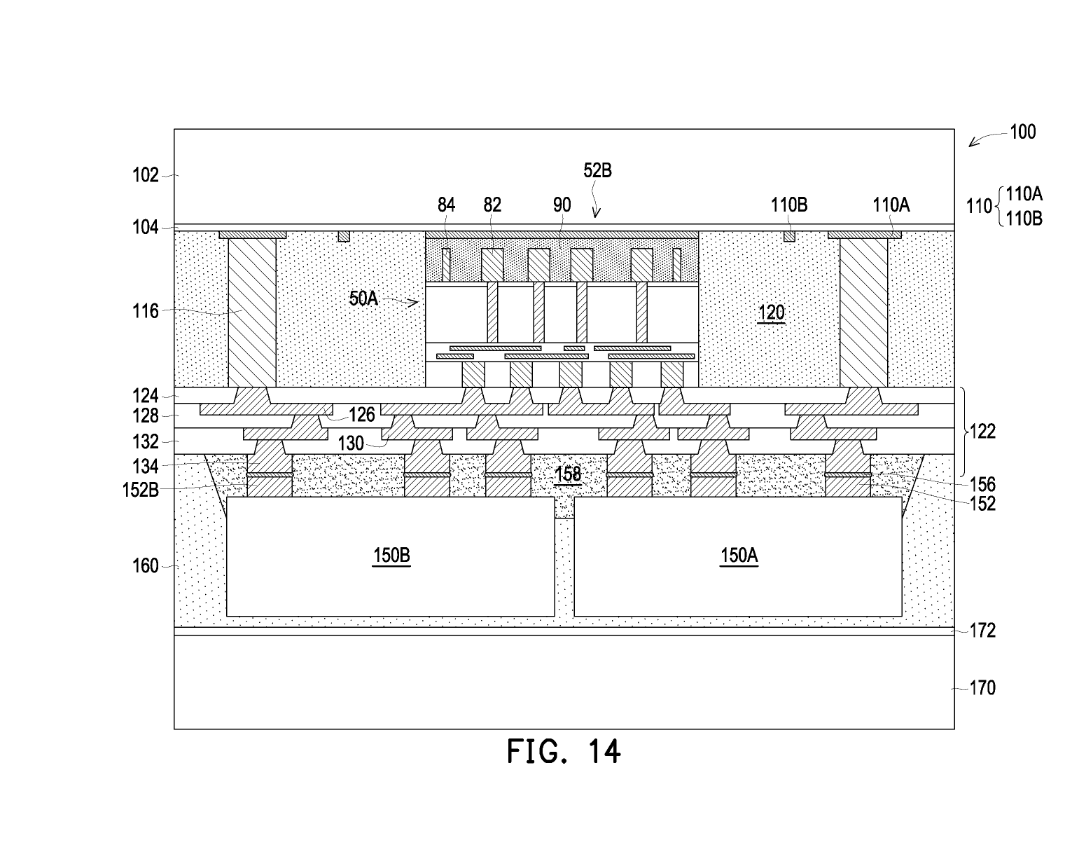

In FIG. 14, the intermediate structure shown in FIG. 13 is flipped over and disposed on a second carrier substrate 170 or other suitable support structure for subsequent processing. In some embodiments, the second carrier substrate 170 is attached to the encapsulant 160 by a release layer 172. In some embodiments, the second carrier substrate 170 is a substrate such as a bulk semiconductor or a glass substrate having a wafer or panel shape or the like. The release layer 172 may be formed of a polymer-based material, which may be removed along with the second carrier substrate 170 from the structure after processing. In some embodiments, the release layer 172 is an epoxy-based thermal-release material, which loses its adhesive property when heated, such as a light-to-heat-conversion (LTHC) release coating. In other embodiments, the release layer 172 may be an ultra-violet (UV) glue, which loses its adhesive property when exposed to UV lights. The release layer 172 may be dispensed as a liquid and cured, may be a laminate film laminated onto the second carrier substrate 170, or may be the like. In some embodiments, the release layer 172 may be different from the release layer 104. For example, the release layer 172 and the release layer 104 may react and lose their adhesives by receiving lights of different wavelengths.

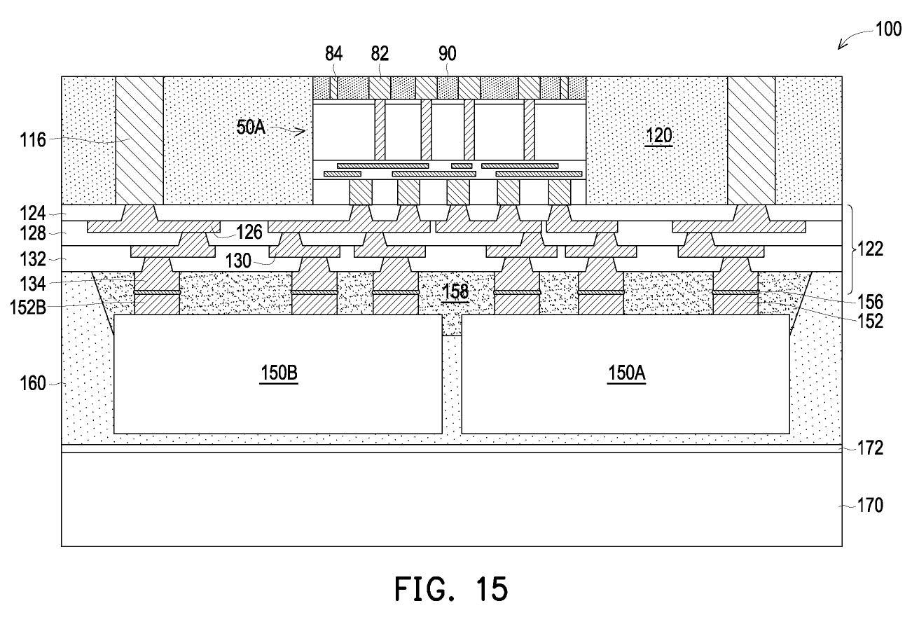

In FIG. 15, a planarization process is performed at the back side 52B of the semiconductor substrate 52, such as on the encapsulant 120 and the encapsulant 90, to expose the through vias 116 and the metallization features 80. In some embodiments, a de-bonding process may be performed to detach the first carrier substrate 102 before the planarization process. In some embodiments, the de-bonding process includes projecting a light such as a laser light or a UV light on the release layer 104 so that the release layer 104 decomposes and the first carrier substrate 102 can be removed. In some embodiments, the de-bonding process is skipped, and the planarization process includes removing the first carrier substrate 102 and the release layer 104. Whether the de-bonding process is performed, the planarization process may remove materials of the metallization pattern 110 (including the first metallization features 110A and the second metallization features 110B), the adhesive film 92, the through vias 116, encapsulant 90, and/or metallization features 80 until the metallization features 80 and through vias 116 are sufficiently exposed. Top surfaces of through vias 116, first metallization features 82, second metallization features 84, encapsulant 90, and encapsulant 120 are substantially coplanar after the planarization process within process variations. In some embodiments, the first metallization features 82 and the second metallization features 84 have a same height. The planarization process may be, for example, a chemical-mechanical polish (CMP), a grinding process, or the like.

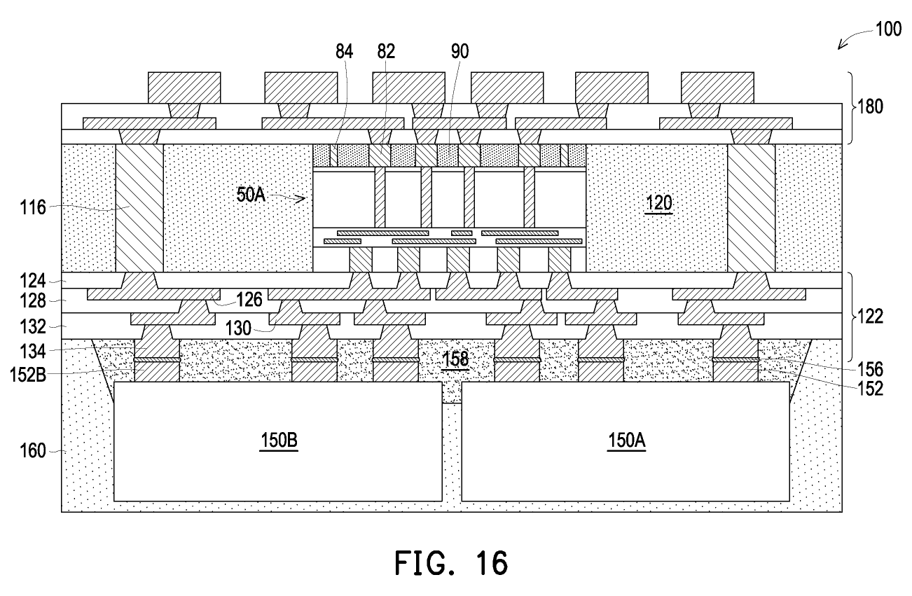

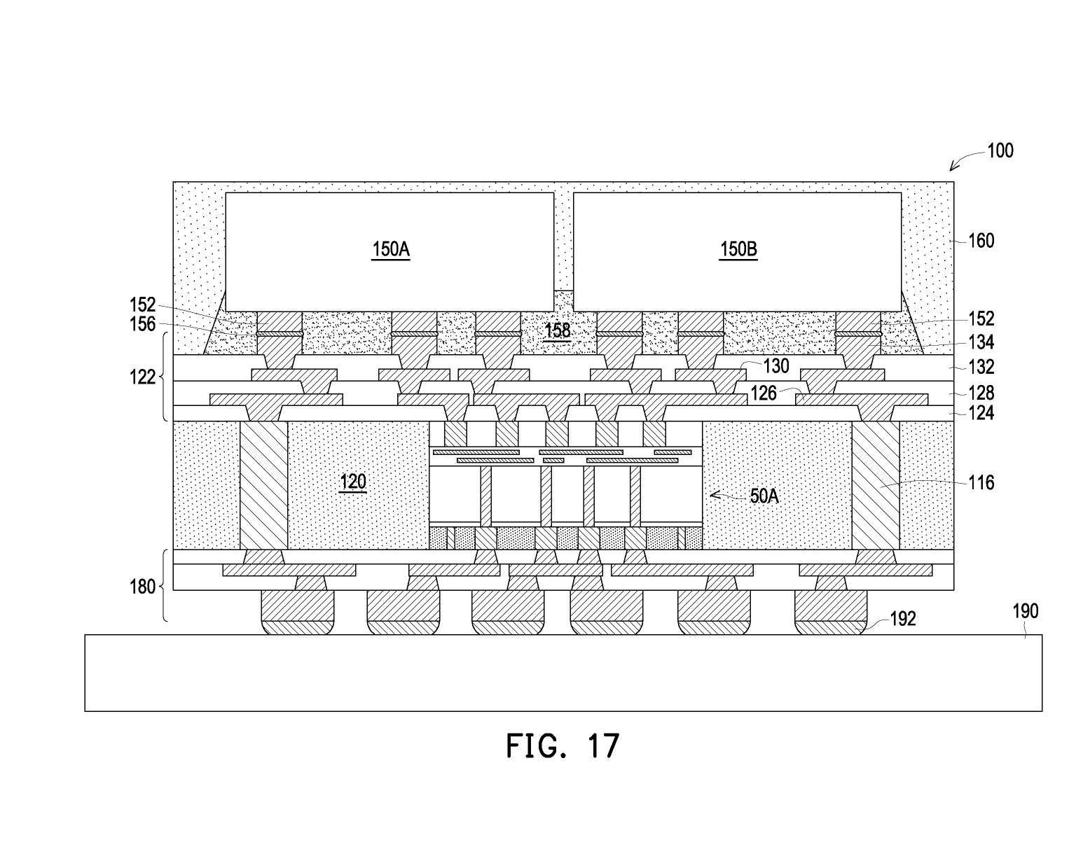

In FIG. 16, a back-side redistribution structure 180 is formed on the encapsulant 160 and at the back side 52B of the semiconductor substrate 52. As illustrated in FIG. 16, the back-side redistribution structure 180 extends over the encapsulant 120, through vias 116, and interconnect structure 50A. The back-side redistribution structure 180 may be formed in a manner similar to the front-side redistribution structure 122 although more or less layers of dielectric layers and metallization patterns can be used. For example, the back-side redistribution structure 180 may have conductive elements that are in physical contact with the first metallization features 82. The back-side redistribution structure 180 may also include a dielectric layer sealing exposed surfaces of the second metallization features 84. In some embodiments, the topmost metallization pattern of the back-side redistribution structure 180 includes conductive pads or protruding bumps for external connections.

Again, the processes discussed above may be performed at the wafer or panel level, and a singulation process is performed. For example, a de-bonding process may be performed to detach the second carrier substrate 170 and the release layer 172. The intermediate structure may be placed on a tape (not shown), and a singulation process is performed by scribing along scribe line regions (not shown). For example, the singulation process can include sawing the back-side redistribution structure 180, the encapsulant 120, the front-side redistribution structure 122, and the encapsulant 160 by a blade in a single step. In some embodiments, as a result of the singulation process, the outer sidewalls of the back-side redistribution structure 180, the encapsulant 120, the front-side redistribution structure 122, and the encapsulant 160 are laterally coterminous (within process variations). Until the current stage, the semiconductor package 100 containing the interconnect structure 50A, front-side redistribution structure 122, back-side redistribution structure 180, through vias 116, and integrated circuit devices 150 are formed by a simplified method, such as using only two carrier substrates 102 and 170.

In FIG. 17, one or more of the singulated packages obtained in FIG. 16 is attached to a substrate 190 using the conductive connectors 192. The substrate 190 may be an interposer, a core substrate, a coreless substrate, a printed circuit board (PCB), a package substrate, or the like. The substrate 190 may include active and/or passive devices (not separately illustrated). Devices such as transistors, capacitors, resistors, combinations thereof, and the like may be used to generate the structural and functional requirements of the design for the system. The devices may be formed using any suitable methods. The conductive connectors 192 may include solder or other suitable materials.

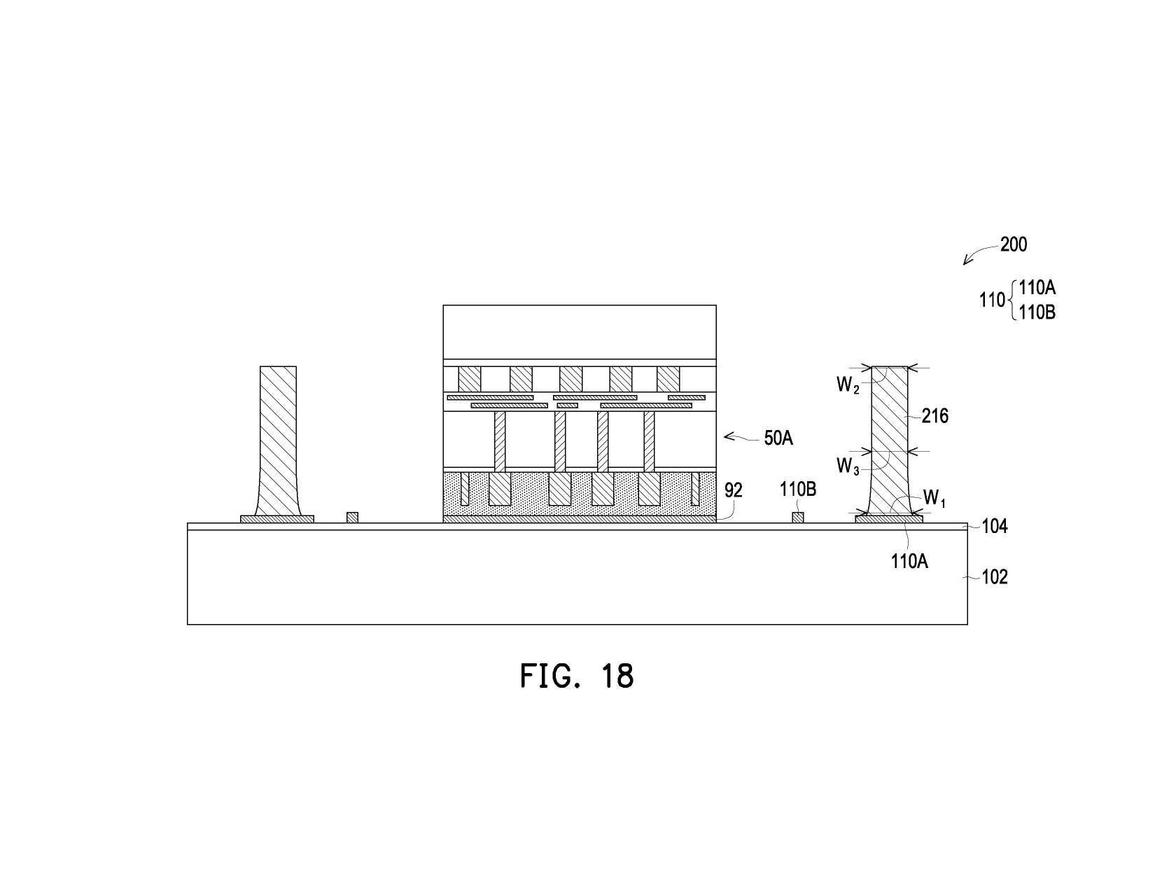

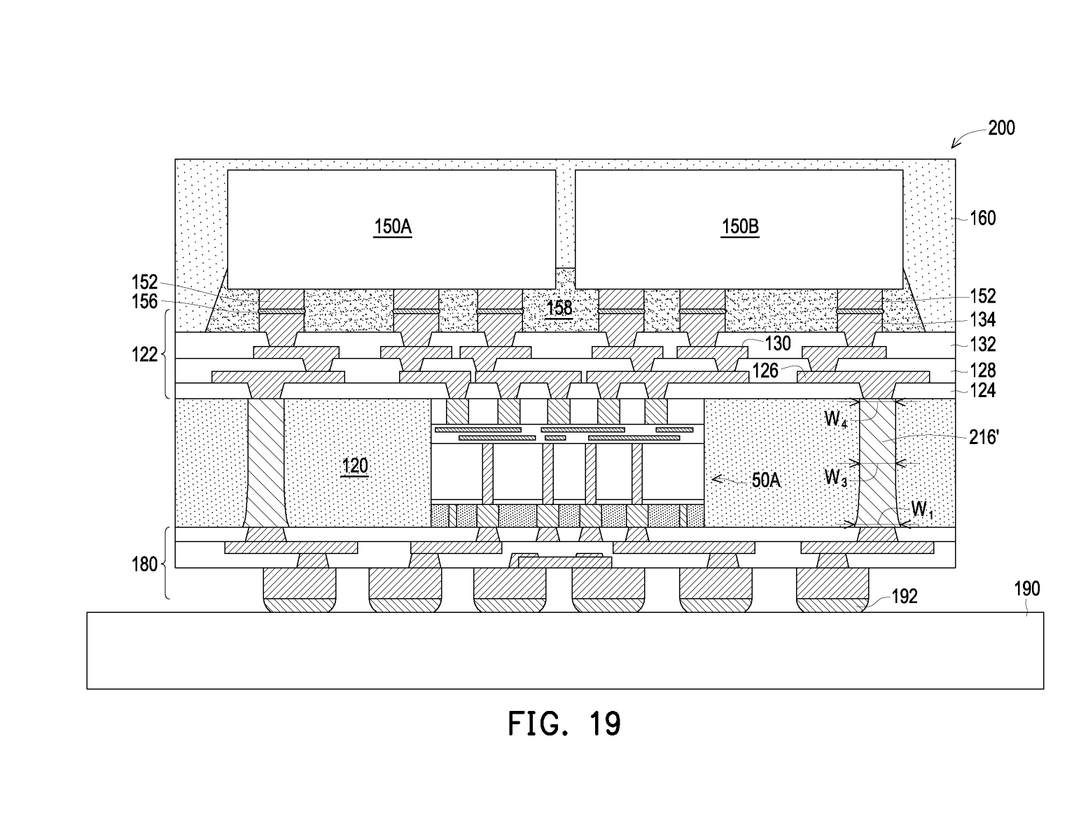

FIGS. 18 and 19 illustrate cross-sectional views of intermediate stages in the manufacturing a semiconductor package 200, in accordance with some embodiments. The semiconductor package 200 may be formed using similar processing steps for the semiconductor package 100, where similar referencing numerals represent similar features. In particular, the processing illustrated in FIG. 18 assumes the processing illustrated in FIGS. 1-8 was performed prior. In some embodiments of the semiconductor package 200, through vias 216 having curved sidewalls are provided.

Referring to FIG. 18, through vias 216 are formed over the first metallization features 110A of the metallization pattern 110, in accordance with some embodiments. A photoresist is deposited over the first carrier substrate 102 and patterned to expose at least a portion of the first metallization features 110A while burying the second metallization features 110B. The photoresist may be formed by spin coating or the like and may be exposed to light for patterning. The pattern of the photoresist corresponds to the through vias 216. A conductive material is formed in the openings of the photoresist and on the exposed portions of the first metallization features 110A. The conductive material may comprise a metal, like copper, titanium, tungsten, aluminum, or the like. In some embodiments, the conductive material may be formed by plating, such as electroplating or electroless plating, or the like, directly on the first metallization features 110A without a seed layer. The photoresist may be removed after the through vias 216 are formed, by an acceptable ashing or stripping process, such as using an oxygen plasma or the like.

The through vias 216 are designed or manufactured to have curved sidewalls, in accordance with some embodiments. The through vias 216 may have a bottom having a first width W₁ and a top having a second width W₂, and the second width W₂ is less than the first width W₁. In some embodiments, the through vias 216 may have a third width W₃ at its half height, and the third width W₃ is less than the first width W1. As illustrated in FIG. 18, the third width W₃ is greater than the second width W₂, although the third width W₃ can be less than the second width W₂, in accordance with some embodiments. The widths of the through vias 216 may be controlled by, for example, electroplating parameters or the shapes of the openings of the photoresist.

After the intermediate structure illustrated in FIG. 18 is formed, the process proceeds by performing the processes as illustrated in FIG. 10-17. As a result, a semiconductor package 200 illustrated in FIG. 19 is provided. Some portions of the through vias 216 may be removed along with the metallization pattern 110 in proceeding the processes as illustrated in FIGS. 10-17, thereby forming through vias 216’ in FIG. 19. As illustrated in FIG. 19, the bottom of the through vias 216’ may still have a relatively wide bottom physically and electrically coupled to the back-side redistribution structure 180 and a relatively narrow top physically and electrically coupled to the front-side redistribution structure 122. For example, the top of the through vias 216’ may have a fourth width W₄ that is less than the first width W₁. In some embodiments, the fourth width W₄ is less than the third width W₃.

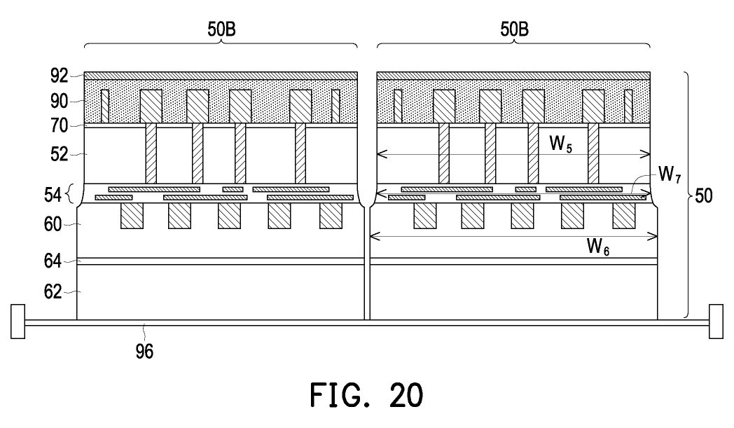

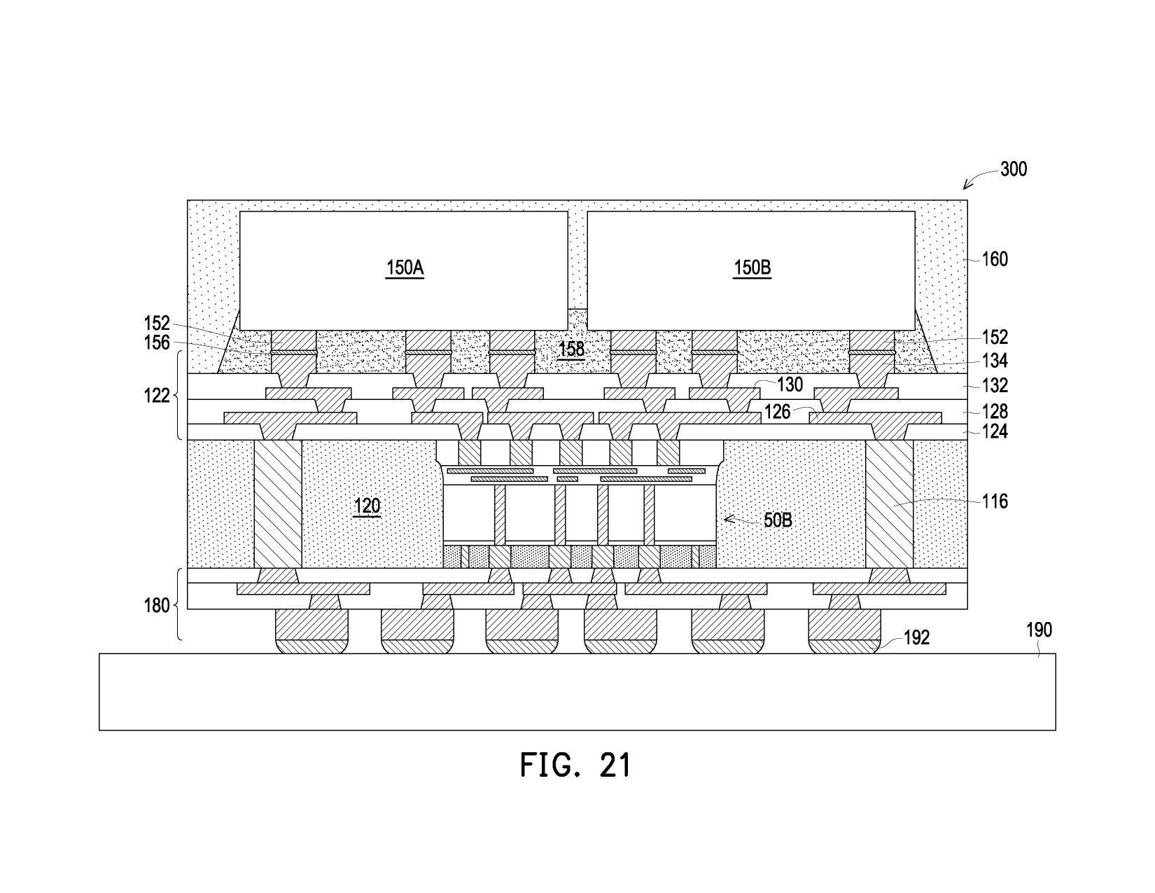

FIG. 20 illustrates a cross-sectional view of interconnect structures 50B, and FIG. 21 illustrates a cross-sectional view of a semiconductor package 300 including the interconnect structure 50B, in accordance with some embodiments. The interconnect structure 50B and the semiconductor package 300 may be formed using similar processing steps for forming the interconnect structure 50A and the semiconductor package 100, respectively, where similar referencing numerals represent similar features. In particular, the processing illustrated in FIG. 20 assumes the processing illustrated in FIGS. 1 to 6 was performed prior. In some embodiments, the interconnect structures 50B are formed by singulating the interconnect structure 50 by multiple steps.

Referring to FIG. 20, the interconnect structure 50 as illustrated in FIG. 6 is singulated by a multi-step singulating process. For example, the singulation process may include a first step of mechanically sawing that saws the interconnect structure 50 to a depth near the routing structure 54, a second step of laser ablating at least the routing structure 54, and a third step of mechanically sawing remaining parts of the interconnect structure 50. In such embodiments, the routing structure 54, which may be fragile and be prone to be cracked or damaged in the multi-step singulation process can have reduced or no cracks or damages by using laser ablation, since laser ablation would generate less mechanical stress than mechanical sawing. Because laser ablation may have its issues in ablating the whole interconnect structure 50, such as slow, hard to maintain constant and high power for a long period of time, prone to cause overheating, high operation cost, and etc. The multiple steps of singulation process may provide improved manufacturing speed, yield, and reliability with reduced cost.

In some embodiments, the multi-step singulation process may include a first step using a first blade having a relatively wide width to saw a main portion of the interconnect structure 50 and a second step of laser ablating the routing structure 54. The relatively wide first blade ensures a clear path for the subsequent laser ablation process. As a result of the laser ablation, the routing structure 54 may have curved sidewalls. The multi-step singulation process may also include using a second blade having a relatively narrow width, such as corresponding to the width of the laser ablation, to saw the remaining parts of the interconnect structure 50. This relatively narrow width blade is used, in some embodiments, to ensure that the singulation process does not cause damage to the routing structure 54. In such embodiments, the adhesive film 92, the encapsulant 90, the insulating layer 70, and at least a portion of the semiconductor substrate 52 of a singulated interconnect structure 50B may have a fifth width W₅. The encapsulant 60, the release layer 64, and the carrier substrate 62 may have a sixth width W₆ less than the fifth width W₅. The routing structure 54 may have curved sidewalls and have a seventh width W₇ at its half height, and the seventh width W₇ is between the fifth width W₅ and the sixth width W₆. The singulated interconnect structure 50B may then be integrated into a semiconductor package 300 by proceeding similar process illustrated in FIG. 8-17, and the resulting structure of the semiconductor package 300 is illustrated in FIG. 21 (due to scale, the curvature of the sidewalls of interconnect structure 50B is not obvious in FIG. 21; these features are more readily discernible from FIG. 20, which illustrates interconnect structure 50B of FIG. 21 at a greater scale of magnification and hence detail). Although not shown in FIG. 21, the through vias 116 in the semiconductor package 300 can be replaced with the through vias 216’.

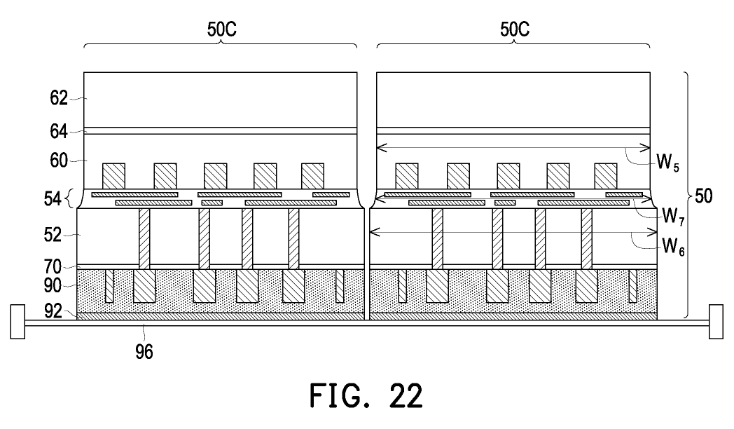

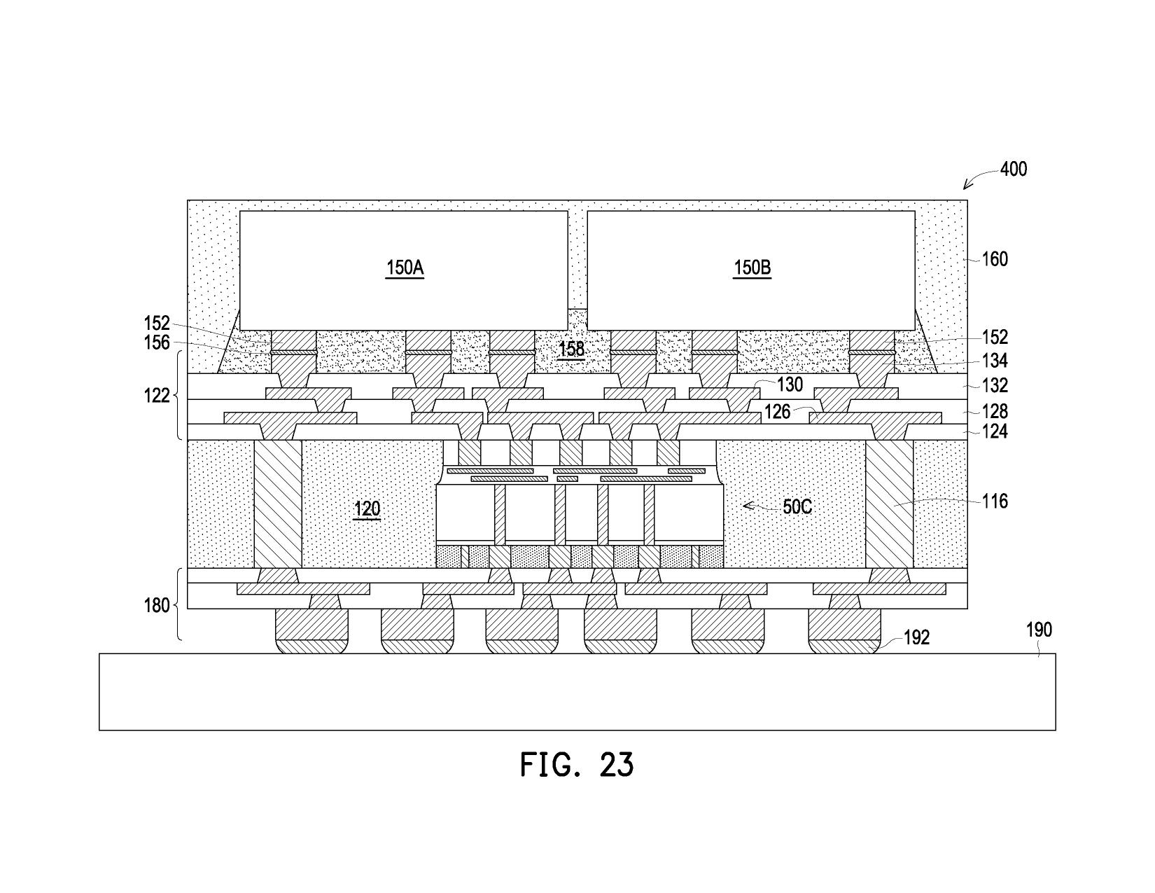

FIG. 22 illustrates a cross-sectional view of singulated interconnect structures 50C, and FIG. 23 illustrates a cross-sectional view of a semiconductor package 400 including the interconnect structure 50C, in accordance with some embodiments. The interconnect structure 50C and the semiconductor package 400 may be formed using similar processing steps for forming the interconnect structure 50A and the semiconductor package 100, respectively, where similar referencing numerals represent similar features. In particular, the processing illustrated in FIG. 22 assumes the processing illustrated in FIGS. 1 to 6 was performed prior. In some embodiments, the interconnect structures 50C are formed by singulating the interconnect structure 50 by multiple steps.

Referring to FIG. 22, the interconnect structure 50 as illustrated in FIG. 6 is singulated by a multi-step singulation process. The interconnect structure 50 may be flipped over before attaching to the dicing tape 96. As such, the singulation process may start from the carrier substrate 62. For example, the singulation process may include a first step of mechanically sawing that saws the interconnect structure 50 to a depth near the routing structure 54, a second step of laser ablating at least the routing structure 54, and a third step of mechanically sawing remaining parts of the interconnect structure 50. In such embodiments, the routing structure 54, which may be fragile and be prone to be cracked or damaged in the singulation process can have reduced or no cracks or damages by using laser ablation, since laser ablation would generate less mechanical stress than mechanical sawing. The multiple steps of singulation process may provide improved manufacturing speed, yield, and reliability with reduced cost.

In some embodiments, the multi-step singulation process may include a first step using a first blade having a relatively wide width to saw a main portion of the interconnect structure 50 and a second step of laser ablating the routing structure 54. As a result of the laser ablation, the routing structure 54 may have curved sidewalls. The multi-step singulation process may also include using a second blade having a relatively narrow width, such as corresponding to the width of the laser ablation, to saw the remaining parts of the interconnect structure 50. In such embodiments, the carrier substrate 62, the release layer 64, and encapsulant 60 may have the fifth width W₅. The adhesive film 92, the encapsulant 90, the insulating layer 70, and at least a portion of the semiconductor substrate 52 of a singulated interconnect structure 50A may have the sixth width W₆, which may be greater than the fifth width W₅. The routing structure 54 may have curved sidewalls and have the seventh width W₇ at an intermediate point along its sidewalls. The singulated interconnect structure 50C may then be integrated into a semiconductor package 400 by proceeding similar processes illustrated in FIG. 8-17, and the resulting structure of the semiconductor package 300 is illustrated in FIG. 23. Although not shown in FIG. 23, the through vias 116 in the semiconductor package 300 can be replaced with the through vias 216’.

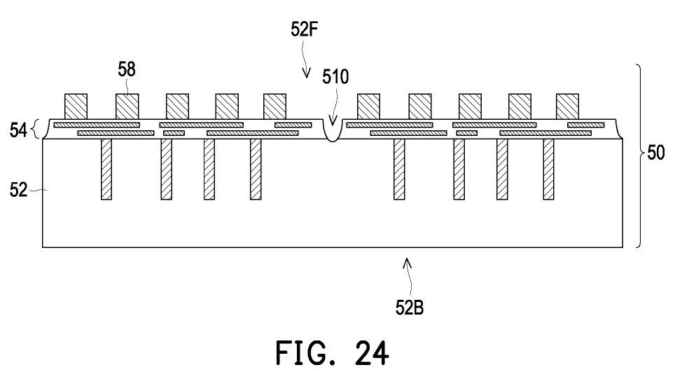

FIGS. 24-26 illustrate cross-sectional views of intermediate stages in the manufacturing interconnect structures 50D, and FIG. 27 illustrates a cross-sectional view of a semiconductor package 500 containing the interconnect structure 50D, in accordance with some embodiments. The interconnect structure 50D and the semiconductor package 500 may be formed using similar processing steps for forming the interconnect structure 50A and the semiconductor package 100, respectively, where similar referencing numerals represent similar features. In particular, the processing illustrated in FIG. 24 assumes the processing illustrated in FIG. 1 was performed prior. In some embodiments, the routing structure 54 of interconnect structure 50 is laser ablated before the singulation processes.

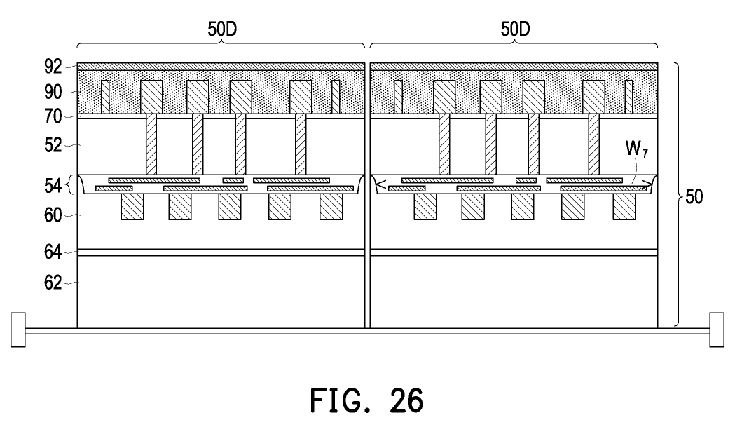

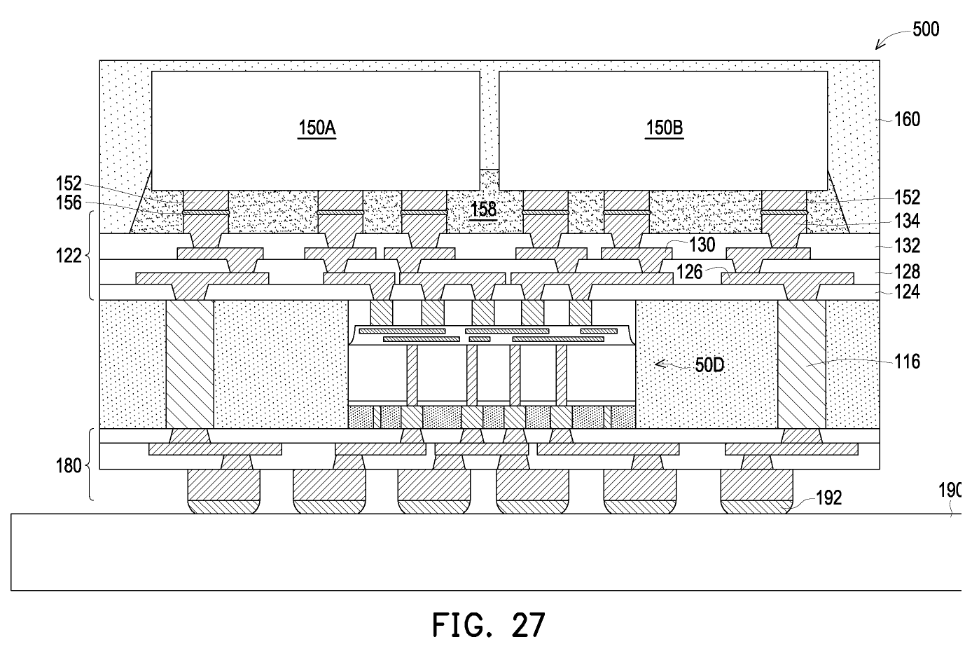

As illustrated in FIG. 24, after forming the conductive features 58 and before forming the encapsulant 60, laser ablation is performed on the routing structure 54 to form laser-ablated openings 510. The laser-ablated openings 510 extend at least through the routing structures 54 in the scribe regions of the interconnect structure 50, in accordance with embodiments. As a result of the laser ablation, the routing structure may 54 have curved sidewalls. For example, in the singulated interconnect structures 50D illustrated in FIG. 26, the routing structure 54 may have curved sidewalls and the seventh width W₇. In some embodiments, the laser-ablating openings 510 have a bottom level with the major surface of the semiconductor substrate 52 or extend into the semiconductor substrate 52.

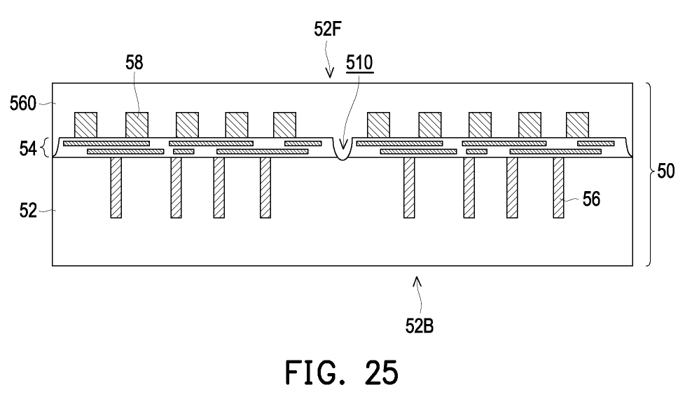

In FIG. 25, after the laser-ablated openings 510 are formed, an encapsulant 560 may be disposed at the front side 52F of the semiconductor substrate 52. The encapsulant 560 may bury the conductive features 58, such that the top surface of the encapsulant 560 is above the top surfaces of the conductive features 58. The encapsulant 560 laterally encapsulates the conductive features 58. The encapsulant 560 may fill in the laser-ablated openings 510 so that encapsulant 560 is in physical contact with the curved sidewalls of the routing structure 54. The portion of the encapsulant 560 in the laser-ablated openings 510 has curved sidewalls corresponding to the shapes of the curved sidewalls of the routing structure 54. The encapsulant 560 may be formed in a similar manner and of a similar material as the encapsulant 60.

Referring to FIG. 26, the interconnect structure 50 may proceed similar processes as illustrated in FIGS. 3-7, including singulating the interconnect structure 50 in a single step as illustrated in FIG. 7. As a result, the interconnect structure 50 may be separated into a plurality of interconnect structures 50D. In some embodiments, the outer sidewalls of the back-side redistribution structure 180, the encapsulant 120, the front-side redistribution structure 122, and the encapsulant 160 in the interconnect structure 50D are laterally coterminous (within process variations). The singulated interconnect structure 50D may then be integrated into a semiconductor package 500 by proceeding similar process illustrated in FIG. 8-17, and the resulting structure of the semiconductor package 500 is illustrated in FIG. 27. Although not shown in FIG. 27, the through vias 116 in the semiconductor package 500 can be replaced with the through vias 216’.

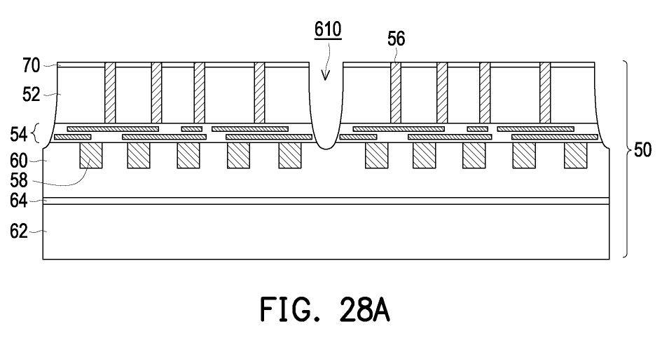

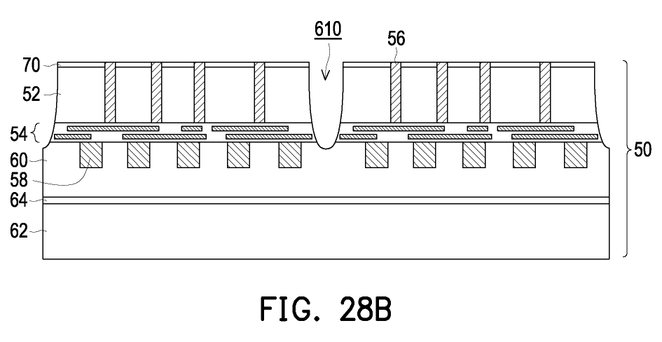

FIGS. 28A, 28B, and 29 to 30 illustrate cross-sectional views of intermediate stages in the manufacturing interconnect structures 50E, and FIG. 31 illustrates a cross-sectional view of a semiconductor package 600 containing the interconnect structure 50E, in accordance with some embodiments. The interconnect structure 50E and the semiconductor package 600 may be formed using similar processing steps for forming the interconnect structure 50A and the semiconductor package 100, respectively, where similar referencing numerals represent similar features. In particular, the processing illustrated in FIG. 28 assumes the processing illustrated in FIG. 4 was performed prior. In some embodiments, the routing structure 54 of interconnect structure 50 is laser ablated before the singulation processes.

As illustrated in FIG. 28A, after exposing the through vias 56, laser ablation is performed on the back side 52B of the semiconductor substrate 52, thereby forming laser-ablated openings 610, in accordance with some embodiments. The laser-ablated openings may at least extend at least through the insulating layer 70, the semiconductor substrate 52, and the routing structure 54 in the scribe regions of the interconnect structure 50. As a result of the laser ablation, the routing structure may 54 have curved sidewalls. For example, in the singulated interconnect structures 50E illustrated in FIG. 26, the routing structure 54 may have curved sidewalls and the seventh width W₇. In some embodiments, the laser-ablating openings 610 have a bottom level with the major surface of the encapsulant 60 adjacent to the routing structure 54 or extending into the encapsulant 60.

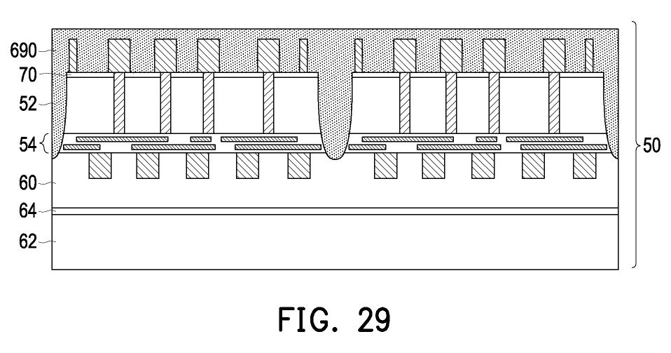

After the laser-ablating process, metallization features 80 are formed at the back side 52B of the semiconductor substrate 52, as illustrated in FIG. 29. Metallization features 80 can be formed using processes similar to those described above with reference to the processes illustrated in FIG. 5. Alternatively, and as illustrated by FIG. 28B, metallization features 80 can be formed prior to the laser-ablating process. Proceeding from the process illustrated in FIG. 28A or 28B, after the laser-ablated openings 510 are formed, an encapsulant 690 may be disposed at the back side 52B of the semiconductor substrate 52. The encapsulant 690 may bury the metallization features 80, such that the top surface of the encapsulant 690 is above the top surfaces of the metallization features 80. The encapsulant 690 laterally encapsulates the metallization features 80, including encapsulating the first metallization features 82 and the second metallization features 84. The encapsulant 690 may fill in the laser-ablated openings 610 so that encapsulant 690 is in physical contact with the curved sidewalls of the semiconductor substrate 52 and the curved sidewalls of the routing structure 54. The portion of the encapsulant 690 in the laser-ablated openings 610 has curved sidewalls corresponding to the shapes of the curved sidewalls of the semiconductor substrate 52 and the curved sidewalls of the routing structure 54. The encapsulant 690 may be formed in a similar manner and of a similar material as the encapsulant 90.

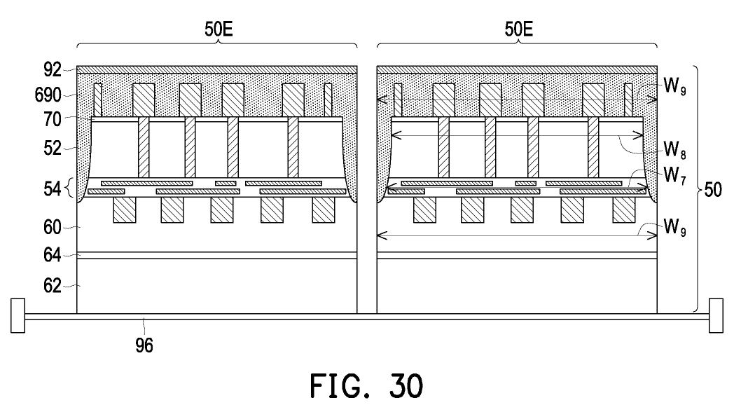

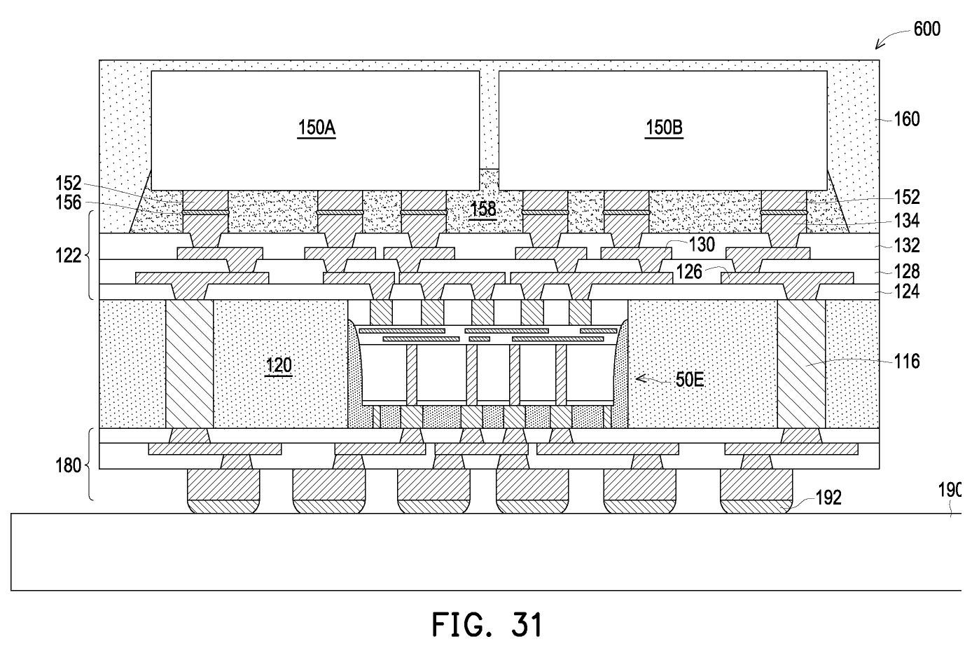

Referring to FIG. 30, the interconnect structure 50 may proceed similar processes as illustrated in FIGS. 5-7, including singulating the interconnect structure 50 in a single step as illustrated in FIG. 7. As a result, the interconnect structure 50 may be separated into a plurality of interconnect structures 50E. In some embodiments, the outer sidewalls of adhesive film 92, encapsulant 90, encapsulant 60, release layer 64, and carrier substrate 62 in the interconnect structure 50E are laterally coterminous (within process variations). For example, the adhesive film 92, the encapsulant 90, a major portion of the encapsulant 60, the release layer 64, and the carrier substrate 62 may have an eight width W₈. The semiconductor substrate 52 may have a ninth width W₉ at a level of its half height, which may be less than the seventh width W₇ and the eighth width W₈. The singulated interconnect structure 50E may then be integrated into a semiconductor package 600 by proceeding similar process illustrated in FIG. 8-17, and the resulting structure of the semiconductor package 600 is illustrated in FIG. 31. Although not shown in FIG. 31, the through vias 116 in the semiconductor package 600 can be replaced with the through vias 216’.

A semiconductor package containing an interconnect structure is provided, which can be manufactured by a simplified method, such as using fewer carrier substrates for forming various components at opposite sides of the interconnect structure. The interconnect structure may be singulated by multi-step singulation processes to effectively protect the routing structure of the interconnect structure from being damaged. The interconnect structure may also include electrically isolated metallization features as alignment marks that can help align the interconnect structure and/or the semiconductor package in the manufacturing of the semiconductor package.

In accordance with some embodiments disclosed herein, a semiconductor package may include a first die and a second die, and an interconnect structure attached to the first die and the second die. The interconnect structure may include a semiconductor substrate comprising a first side and a second side opposite to the first side, the first side being closer to the first die and the second die than the second side, a routing structure disposed at the first side of the semiconductor substrate, wherein the first die is electrically coupled to the second die through at least the routing structure, and a metallization pattern disposed at the second side of the semiconductor substrate, wherein the metallization pattern comprises a first metallization feature and a second metallization feature, wherein the second metallization feature is electrically isolated, and a through via extending through the semiconductor substrate and electrically coupling the routing structure to the first metallization feature.

In accordance with other embodiments disclosed herein, a semiconductor package may include a first redistribution structure comprising a conductive element, and an interconnect structure over the first redistribution structure. The interconnect structure may include a semiconductor substrate having a first side and a second side, the second side being opposite to the first side, the second side facing the first redistribution structure, a routing structure at the first side of the semiconductor substrate, and a metallization pattern at the second side of the semiconductor substrate, wherein the metallization pattern comprises a first metallization feature and a second metallization feature, wherein the first metallization feature is in physical contact with the conductive element of the first redistribution structure, and the second metallization feature is electrically isolated. The package may further include a first encapsulant over the first redistribution structure and laterally surrounding the interconnect structure, a second redistribution structure over the interconnect structure and the first encapsulant, and a semiconductor die over the second redistribution structure.

In accordance with yet other embodiments disclosed herein, a method of forming a semiconductor package may include steps of forming a first metallization feature over a first carrier substrate, forming a through via over the first metallization feature, and placing an interconnect structure over the first carrier substrate, wherein the interconnect structure comprises a semiconductor substrate, a routing structure at a first side of the semiconductor substrate, and a second metallization feature at a second side of the semiconductor substrate opposite to the first side, wherein the first side of the semiconductor substrate faces away from the first carrier substrate. The method may include further steps of forming a first encapsulant over the first metallization feature, the interconnect structure, and the through via, performing a first planarization process to expose the interconnect structure and the through via, attaching a second carrier substrate at the first side of the semiconductor substrate, and after the second carrier substrate is attached, performing a second planarization process at the second side of the semiconductor substrate. The method may further include forming a redistribution structure at the second side of the semiconductor substrate, wherein the redistribution structure is in physical contact with the second metallization feature.

Those skilled in the art will recognize herein embodiments that may provide for a method including steps of forming a plurality of interconnect structures, the plurality of interconnect structures being physically connected together. Respective interconnect structures of the plurality of interconnect structures may include a substrate, a routing structure on a first side of the substrate, a through substrate via (TSV) extending through the substrate, and a first metallization pattern on a second side of the substrate, the first metallization pattern including first metallization features and second metallization features. The method may further include singulating a first interconnect structure from the plurality of interconnect structures using a multi-step singulation process, wherein the routing structure of the first interconnect structure has curved sidewalls as a result of the multi-step singulation process, placing the first interconnect structure on a surface and forming on the surface a second metallization pattern including third metallization features and fourth metallization features, forming respective through vias on respective third metallization features, and encapsulating the first interconnect structure and the respective through vias in an encapsulant, forming a frontside redistribution structure on a front side of the first interconnect structure, the respective through vias, and the encapsulant, respectively, adhering a first and a second integrated circuit device to the frontside redistribution structure; and forming a backside redistribution structure on a back side opposite the front side of the first interconnect structure, the respective through vias, and the encapsulant, respectively.

Those skilled in the art will recognize herein other embodiments that may provide for a method including steps of forming a plurality of interconnect structures. Each interconnect structure of the plurality of interconnect structures may include a substrate, a routing structure on a front side of the substrate, conductive pads on the front side of the substrate and embedded in a first encapsulant, and through substrate vias (TSV) extending from a front side of the substrate at least partially to a back side of the substrate opposite the front side. The method may further include placing the plurality of interconnect structures on a carrier substrate with the conductive pads facing the carrier substrate and the TSVs facing away from the carrier substrate, forming on respective backsides of respective interconnect structures respective first metal features and respective second metal features embedded with a second encapsulant, singulating the plurality of interconnect structures into individual interconnect structures through a multi-step singulation process, placing an individual interconnect structure on a first carrier, forming through vias on the first carrier, and encapsulating the individual interconnect structure and the through vias in a third encapsulant, wherein respective through vias and respective contact pads remain exposed at a surface of the third encapsulant. The method may further include forming a front side redistribution structure over the third encapsulant and electrically contacting respective through vias and respective contact pads;
bonding a first integrated circuit device and a second integrated circuit device to the front side redistribution structure, and encapsulating the first integrated circuit device and the second integrated circuit device in a fourth encapsulant, adhering the fourth encapsulant to a second carrier and removing the first carrier; and forming a back side redistribution structure electrically contacting respective through vias and respective first metal features of the individual interconnect structure.

Other embodiments disclosed herein may inform those skilled in the art of a packaged device including an interconnect structure, wherein the interconnect device may include a substrate and a through silicon via (TSV) extending through the substrate, a routing structure on front side of the substrate, the routing structure including multiple layers of metallization patterns embedded respectively within multiple layers of dielectrics, the routing structure having an outermost sidewall having a concave profile when viewed from a cross-sectional perspective, a contact pad on the routing structure, a first encapsulant surrounding the contact pad, a second contact pad on a back side of the substrate opposite the front side, electrically connected to the TSV, and a second encapsulant surrounding the second contact pad. The packaged device may further include a third encapsulant surrounding the interconnect structure, a front side redistribution structure extending over the third encapsulant and the interconnect structure and electrically contacting the contact pads, a first integrated circuit device and a second integrated circuit device over and electrically contacting the front side redistribution structure, and a back side redistribution structure under and electrically contacting the second contact pads of the interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of interconnect structures, the plurality of interconnect structures being physically connected together, respective interconnect structures of the plurality of interconnect structures including:
a substrate,
a routing structure on a first side of the substrate,
a through substrate via (TSV) extending through the substrate, and
a first metallization pattern on a second side of the substrate, the first metallization pattern including first metallization features and second metallization features ;
singulating a first interconnect structure from the plurality of interconnect structures using a multi-step singulation process, wherein the routing structure of the first interconnect structure has curved sidewalls as a result of the multi-step singulation process;
placing the first interconnect structure on a surface and forming on the surface a second metallization pattern including third metallization features and fourth metallization features;
forming respective through vias on respective third metallization features, and encapsulating the first interconnect structure and the respective through vias in an encapsulant;
forming a frontside redistribution structure on a front side of the first interconnect structure, the respective through vias, and the encapsulant, respectively;
adhering a first and a second integrated circuit device to the frontside redistribution structure; and
forming a backside redistribution structure on a back side opposite the front side of the first interconnect structure, the respective through vias, and the encapsulant, respectively.

2. The method of claim 1, wherein the multi-step singulation process includes a first sawing process through a first portion of the first interconnect structure above the routing structure, a laser ablation process through the routing structure, and a second sawing process through a second portion of the first interconnect structure below the routing structure.

3. The method of claim 2, wherein the first portion of the first interconnect structure includes the substrate.

4. The method of claim 2, wherein the multi-step singulation process includes laser ablating through the routing structure before sawing through remaining portions of the first interconnect structure.

5. The method of claim 4, wherein the laser ablating forms a cavity and further comprising filling the cavity with a second encapsulant.

6. The method of claim 1, wherein the step of forming respective through vias on respective third metallization features includes a metal plating process and further wherein parameters of the metal plating process are controlled to form through vias having curved sidewalls.

7. The method of claim 1, wherein the second metallization features form alignment marks and further comprising aligning the first interconnect structure to another structure using the alignment marks.

8. The method of claim 2, wherein the laser ablation process generates less mechanical stress on the routing structure than the first sawing process.

9. A method comprising:
forming a plurality of interconnect structures, each interconnect structure of the plurality of interconnect structures including:
a substrate,
a routing structure on a front side of the substrate,
conductive pads on the front side of the substrate and embedded in a first encapsulant, and
a through substrate vias (TSV) extending from a front side of the substrate at least partially to a back side of the substrate opposite the front side;
placing the plurality of interconnect structures on a carrier substrate with the conductive pads facing the carrier substrate;
forming on respective backsides of respective interconnect structures respective first metal features and respective second metal features embedded with a second encapsulant;
singulating the plurality of interconnect structures into individual interconnect structures through a multi-step singulation process;
placing an individual interconnect structure on a first carrier;
forming through vias on the first carrier;
encapsulating the individual interconnect structure and the through vias in a third encapsulant, wherein respective through vias and respective contact pads remain exposed at a surface of the third encapsulant;
forming a front side redistribution structure over the third encapsulant and electrically contacting respective through vias and respective contact pads;
bonding a first integrated circuit device and a second integrated circuit device to the front side redistribution structure, and encapsulating the first integrated circuit device and the second integrated circuit device in a fourth encapsulant;
adhering the fourth encapsulant to a second carrier and removing the first carrier; and
forming a back side redistribution structure electrically contacting respective through vias and respective first metal features of the individual interconnect structure.

10. The method of claim 9, wherein the step of encapsulating the individual interconnect structure and the through vias in the third encapsulant further includes planarizing the third encapsulant to expose the respective through vias and respective contact pads.

11. The method of claim 10, further comprising removing the carrier substrate prior to the planarizing.

12. The method of claim 9, wherein the step of singulating the plurality of interconnect structures into individual interconnect structures includes a first sawing process followed by a laser ablation process that cuts through the routing structure followed by a second sawing process.

13. The method of claim 9, wherein the step of singulating the plurality of interconnect structures into individual interconnect structures includes laser ablating through the routing structure before the conductive pads are embedded in the first encapsulant.

14. The method of claim 9, wherein the step of singulating the plurality of interconnect structures into individual interconnect structures includes laser ablating through the substrate and through the routing structure before the respective first metal features (82) and respective second metal features are embedded within the second encapsulant.

15. A packaged device comprising:
an interconnect structure including:
a substrate and a through silicon via (TSV) extending through the substrate,
a routing structure on front side of the substrate, the routing structure including multiple layers of metallization patterns embedded respectively within multiple layers of dielectrics, the routing structure having an outermost sidewall having a concave profile when viewed from a cross-sectional perspective,
a contact pad on the routing structure,
a first encapsulant surrounding the contact pad, ;
a second contact pad on a back side of the substrate opposite the front side, electrically connected to the TSV, and
a second encapsulant surrounding the second contact pad;
a third encapsulant surrounding the interconnect structure;
a front side redistribution structure extending over the third encapsulant and the interconnect structure and electrically contacting the contact pad;
a first integrated circuit device and a second integrated circuit device over and electrically contacting the front side redistribution structure; and
a back side redistribution structure under and electrically contacting the second contact pad of the interconnect structure.

16. The packaged device of claim 15, wherein the routing structure has a first cross-sectional width at a bottommost surface closest to the substrate and a second cross-sectional width different than the first cross-section width at topmost surface furthest from the substrate.

17. The packaged device of claim 16, wherein the second cross-sectional width is less than the first cross-sectional width.

18. The packaged device of claim 17, wherein the first encapsulant extends between the outermost sidewall of the routing structure and the third encapsulant.

19. The packaged device of claim 18, wherein the second cross-sectional width is greater than the first cross-sectional width.

20. The packaged device of claim 19, wherein the second encapsulant extends between the outermost sidewall of the routing structure and the third encapsulant.
